(19) United States
(12) Patent Application Publication
(10) Pub. No.: US 2026/0107652 A1
(43) Pub. Date: Apr. 16, 2026

(54) DISPLAY DEVICE AND ELECTRONIC APPARATUS INCLUDING THE SAME

(71) Applicant: Samsung Display Co., Ltd., Yongin-si (KR)

(72) Inventor: Younjoo Lee, Yongin-si (KR)

(21) Appl. No.: 19/351,112

(22) Filed: Oct. 6, 2025

(30) Foreign Application Priority Data
Oct. 11, 2024 (KR) 10-2024-0138427

(51) Int. Cl. H10K 59/131; H10K 102/00

(52) U.S. Cl. CPC H10K 59/131; H10K 2102/311

(57) ABSTRACT

A display device includes a plurality of island portions spaced apart from each other and including a driving circuit and a plurality of bridge portions connecting two adjacent ones of the island portions from among the plurality of island portions to each other. At least one of the plurality of bridge portions includes a portion of a first structure that is connected to at least one of the plurality of island portions and has a curved shape, the first structure includes a first-1 structure having an arc shape with a central angle of (90+X) degrees, and X is in a range of 5 to 55.

### CROSS-REFERENCE TO RELATED APPLICATION

The present application claims priority to and the benefit of Korean Patent Application No. 10-2024-0138427, filed on October 11, 2024, in the Korean Intellectual Property Office, the entire disclosure of which is incorporated herein by reference.

### BACKGROUND

1. Field

Aspects of embodiments of the present disclosure relate to a display device and an electronic apparatus including the same.

### 2. Description of the Related Art

With the development of display devices that visually display electrical signals, various display devices having desirable characteristics, such as thinness, low weight, and low power consumption, have been introduced. For example, flexible display devices that are foldable or rollable have been introduced. Recently, stretchable display devices that can be deformed into various shapes have been the subject of research and development.

### SUMMARY

Embodiments of the present disclosure include a display device, for example, a flexible display device. However, this is only an example and the scope of the present disclosure is not limited thereto.

Additional aspects and features of the present disclosure will be set forth, in part, in the description that follows and, in part, will be apparent from the description or may be learned by practice of the presented embodiments of the present disclosure.

According to an embodiment of the present disclosure, a display device includes a plurality of island portions spaced apart from each other and including a driving circuit and a plurality of bridge portions connecting two adjacent ones of the island portions from among the plurality of island portions to each other. At least one of the plurality of bridge portions includes a portion of a first structure that is connected to at least one of the plurality of island portions and has a curved shape, the first structure includes a first-1 structure having an arc shape with a central angle of (90+X) degrees, and X is in a range of 5 to 55.

In an embodiment, the first structure may further include a first-2 structure having an arc shape with a central angle of (180+2X) degrees and a first-3 structure having an arc shape with a central angle of (90+X) degrees. Each of the first-1 structure and the first-3 structure may be connected to the first-2 structure.

In an embodiment, the first structure may be divided into a first portion and a second portion arranged symmetrically with respect to a first center line crossing the first-2 structure.

In an embodiment, at least one of the plurality of bridge portions may include the first portion.

In an embodiment, at least one of the plurality of bridge portions may include the first portion and the second portion.

In an embodiment, the first structure may have a straight line shape and may further include a first-1 connection structure connecting the first-1 structure to the first-2 structure.

In an embodiment, the first structure may have a straight line shape and may further include a first-2 connection structure connecting the first-2 structure to the first-3 structure.

In an embodiment, radii of the first-1 structure, the first-2 structure, and the first-3 structure may be equal to each other.

In an embodiment, a distance between a center of the first-1 structure and a center of the first-3 structure may be greater than a diameter of the first-2 structure.

In an embodiment, a shortest distance between the first-1 structure and the first-3 structure may be less than a diameter of the first-2 structure.

In an embodiment, X may be 15.

In an embodiment, a distance between two adjacent ones of the island portions from among the plurality of island portions may be 250 μm or less.

According to another embodiment of the present disclosure, an electronic apparatus includes a plurality of island portions spaced apart from each other and including a driving circuit and a plurality of bridge portions connecting two adjacent ones of the island portions from among the plurality of island portions to each other. At least one of the plurality of bridge portions includes a portion of a first structure that is connected to at least one of the plurality of island portions and has a curved shape, the first structure includes a first-2 structure having an arc shape with a central angle of (180+2X) degrees, and X is in a range of 5 to 55.

In an embodiment, the first structure may further include a first-1 structure having an arc shape with a central angle of (90+X) degrees and a first-3 structure having an arc shape with a central angle of (90+X) degrees. Each of the first-1 structure and the first-3 structure may be connected to the first-2 structure.

In an embodiment, the first structure may be divided into a first portion and a second portion arranged symmetrically with respect to a first center line crossing the first-2 structure.

In an embodiment, at least one of the plurality of bridge portions may include the first portion.

In an embodiment, at least one of the plurality of bridge portions may include the first portion and the second portion.

In an embodiment, the first structure may have a straight line shape and may further include a first-1 connection structure connecting the first-1 structure to the first-2 structure.

In an embodiment, the first structure may have a straight line shape and may further include a first-2 connection structure connecting the first-2 structure to the first-3 structure.

According to another embodiment of the present disclosure, an electronic apparatus includes a display device including: a plurality of island portions spaced apart from each other and respectively including a driving circuit and a light emitting element connected to the driving circuit; and a plurality of bridge portions connecting two adjacent ones of the island portions from among the plurality of island portions to each other. The plurality of bridge portions respectfully include wiring lines electrically connected to ones of the driving circuits. At least one of the plurality of bridge portions includes a portion of a first structure that is connected to at least one of the plurality of island portions and has a curved shape. The first structure includes a first-2 structure having an arc shape with a central angle of (180+2X) degrees, and X is in a range of 5 to 55.

Other aspects and features of the present disclosure will be better understood through the accompanying drawings, the detailed description, and the appended claims.

### BRIEF DESCRIPTION OF THE DRAWINGS

The above and other aspects and features of the disclosure will be more apparent from the following description taken in conjunction with the accompanying drawings, in which:

FIG. 1 is a perspective view schematically illustrating a display device according to an embodiment;

FIGS. 2A and 2B are perspective views illustrating the display device shown in FIG. 1 stretched in a first direction;

FIG. 2C is a perspective view illustrating the display device shown in FIG. 1 stretched in a second direction;

FIG. 2D is a perspective view illustrating the display device shown in FIG. 1 stretched in the first direction and the second direction;

FIG. 2E is a perspective view illustrating the display device shown in FIG. 1 stretched in a third direction;

FIG. 3 is a plan view schematically illustrating a display device according to an embodiment;

FIG. 4A is an enlarged plan view of the region IV in FIG. 3 according to an embodiment;

FIG. 4B is an enlarged plan view of the region IV in FIG. 3 according to another embodiment;

FIG. 4C is an enlarged plan view of the region IV in FIG. 3 according to another embodiment;

FIG. 5 is a cross-sectional view schematically illustrating a first island portion and a first bridge portion in a display area of a display device according to an embodiment;

FIGS. 6A to 6C are equivalent circuit diagrams of a sub-pixel of a display device, according to various embodiments;

FIGS. 7A and 7B are cross-sectional views schematically illustrating a light-emitting element of a display device according to various embodiments;

FIG. 8A is an enlarged plan view of a first island portion of a display device according to an embodiment;

FIG. 8B is a plan view illustrating the layout of wirings on a first bridge portion of a display device according to an embodiment;

FIG. 9 illustrates a cross-section taken along the line I-I’ in FIG. 8A and a cross-section taken along the line II-II’ in FIG. 8B;

FIGS. 10A and 10B are enlarged plan views of an island portion and a bridge portion of a display device according to an embodiment;

FIGS. 11 and 12 are schematic plan views of a first structure according to an embodiment;

FIGS. 13A to 15B are enlarged plan views of an island portion and a bridge portion of a display device according to various embodiments;

FIG. 16 is a graph showing strain of a bridge portion with respect to X;

FIG. 17 is a graph showing X with respect to a distance between two adjacent island portions; and

FIGS. 18A to 18G are perspective views schematically illustrating an electronic apparatus including a display device according to various embodiments.

### DETAILED DESCRIPTION

Reference will now be made, in detail, to embodiments, examples of which are illustrated in the accompanying drawings. In this regard, the described embodiments may have different forms and should not be construed as being limited to the descriptions set forth herein. Accordingly, embodiments are merely described below, by referring to the figures, to explain aspects and features of the present description.

The present description allows for various changes and numerous embodiments, and only some embodiments will be illustrated in the drawings and described in detail in the written description. Aspects and features of the present disclosure, and methods of achieving them, will be clarified with reference to embodiments described below, in detail, with reference to the drawings. However, the present disclosure is not limited to the following embodiments and may be embodied in various forms.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being "coupled" or "connected" to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of "may" when describing embodiments of the present disclosure relates to "one or more embodiments of the present disclosure." Expressions, such as “at least one of” and “any one of,” when preceding a list of elements, modify the entire list of elements and do not modify the individual elements of the list. For example, the expression "at least one of a, b, or c" indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms "substantially," "about," and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or "over" the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms "includes," "including," “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of "1.0 to 10.0" is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When a certain embodiment is implemented differently, a specific process sequence may be performed differently from a sequence described herein. For example, two consecutively described processes may be performed substantially at the same time or performed in an order opposite to the stated order.

In the present specification, the expression "in a plan view" means a plane viewed from a direction perpendicular to a substrate. For example, the expression "A and B spaced apart from each other in a plan view" means "A and B spaced apart from each other when viewed from a direction perpendicular to the substrate."

In the present specification, the expression "in a cross-sectional view" means a plane cut in a direction perpendicular to the substrate. For example, the expression "A and B spaced apart from each other in a plan view" means "A and B spaced apart from each other in a plane cut in a direction perpendicular to the substrate."

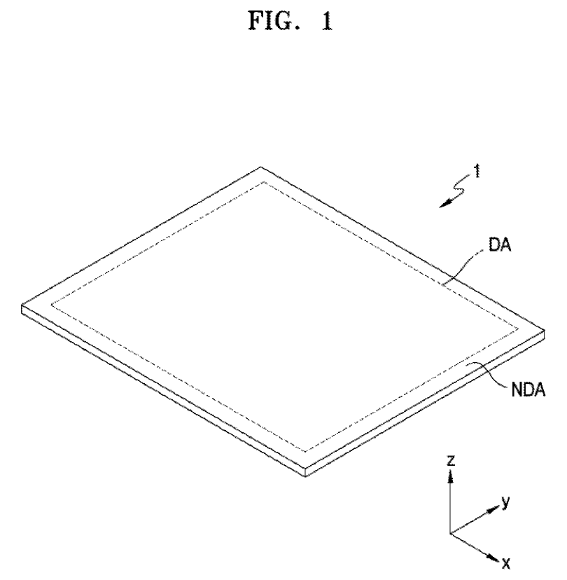

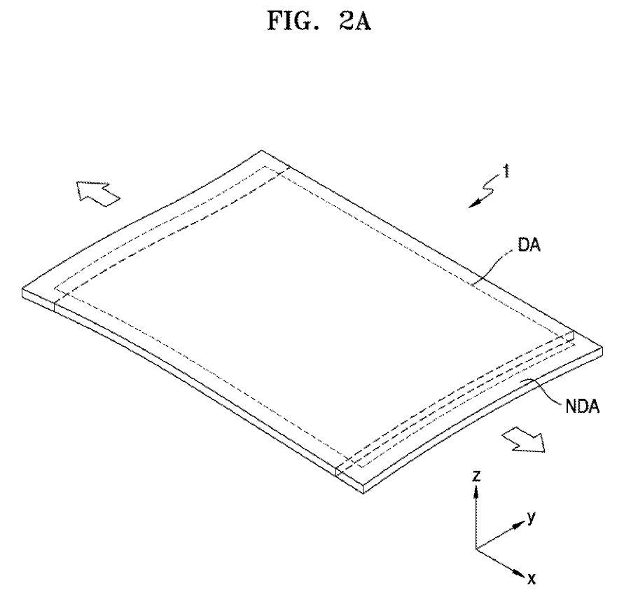

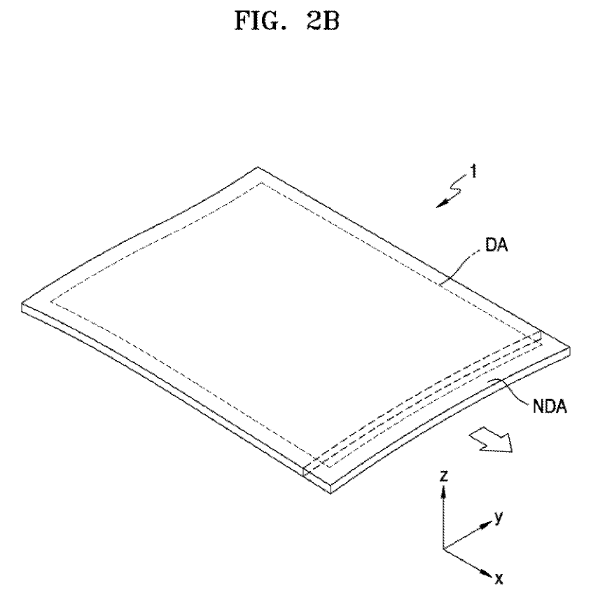

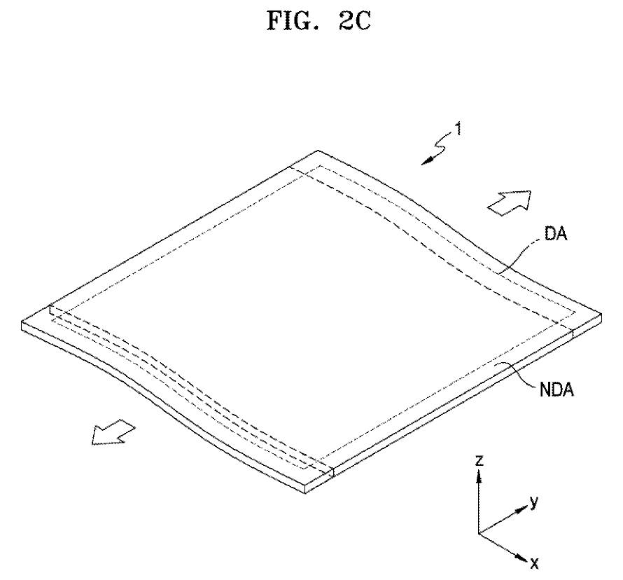

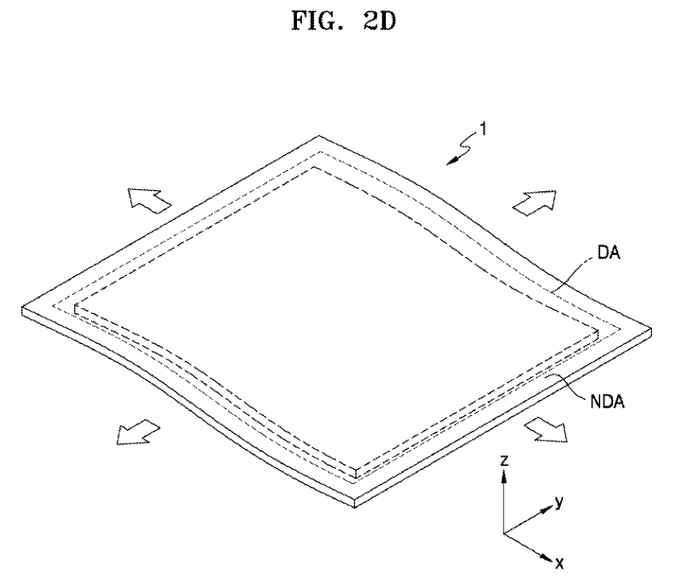

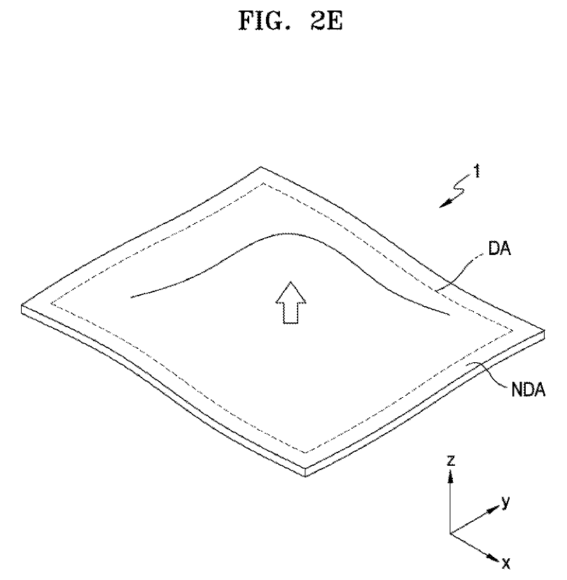

FIG. 1 is a schematic perspective view of a display device 1 according to an embodiment. FIGS. 2A and 2B are perspective views illustrating the display device 1 shown in FIG. 1 stretched in a first direction (e.g., a +x direction and/or a -x direction). FIG. 2C is a perspective view illustrating the display device 1 shown in FIG. 1 stretched in a second direction (e.g., a +y direction and/or a -y direction). FIG. 2D is a perspective view illustrating the display device 1 shown in FIG. 1 stretched in the first direction (e.g., the +x direction and/or the -x direction) and the second direction (e.g., the +y direction and/or the -y direction). FIG. 2E is a perspective view illustrating the display device 1 shown in FIG. 1 stretched in a third direction (e.g., a +z direction and/or a -z direction).

Referring to FIG. 1, the display device 1 may have a display area DA and a non-display area NDA. The display area DA may include a plurality of pixels. The display device 1 may provide (e.g., may display or emit) a certain image by using light emitted from the pixels. The non-display area NDA may be disposed outside the display area DA. The non-display area NDA may completely surround (e.g., may extend around a periphery of) the display area DA.

The display device 1 may be stretched or contracted in various directions. The display device 1 may be stretched in the first direction (e.g., the +x direction and/or the -x direction) by an external force applied by an external object or a user. As illustrated in FIGS. 2A and 2B, the display area DA and/or the non-display area NDA of the display device 1 may be stretched in the first direction (e.g., the +x direction and/or the -x direction). For example, as illustrated in FIG. 2A, the display device 1 may be stretched in the +x direction and the -x direction, or as illustrated in FIG. 2B, the display device 1 may be stretched in the +x direction while one side of the display device 1 is fixed.

The display device 1 may be stretched in the second direction (e.g., the +y direction and/or the -y direction) by an external force applied by an external object or a user. As illustrated in FIG. 2C, the display area DA and/or the non-display area NDA of the display device 1 may be stretched in the +y direction and the -y direction. In another caser, the display device 1 may be stretched in the +y direction or the -y direction while one side of the display device 1 is fixed.

The display device 1 may be stretched in a plurality of directions, for example, the first direction (e.g., the +x direction and/or the -x direction) and the second direction (e.g., the +y direction and/or the -y direction) by an external force applied by an external object or a part of a person’s body. As illustrated in FIG. 2D, the display area DA and/or the non-display area NDA of the display device 1 may be stretched in the ±x direction and the ±y direction.

The display device 1 may be stretched in the third direction (e.g., the +z direction or the -z direction) by an external force applied by an external object or a part of a person’s body. FIG. 2E illustrates a situation in which a portion of the display device 1, for example, a portion of the display area DA protrudes in (or is stretched in) the +z direction. In another case, a portion of the display device 1, for example, a portion of the display area DA may protrude in the -z direction (or may be recessed in the +z direction).

FIGS. 2A to 2E illustrate that the display device 1 is stretched in the first direction, the second direction, and/or the third direction, but the present disclosure is not limited thereto. In another embodiment, the display device 1 may be deformed into various irregular shapes. For example, the display device 1 may be bent or twisted with respect to two or more axes.

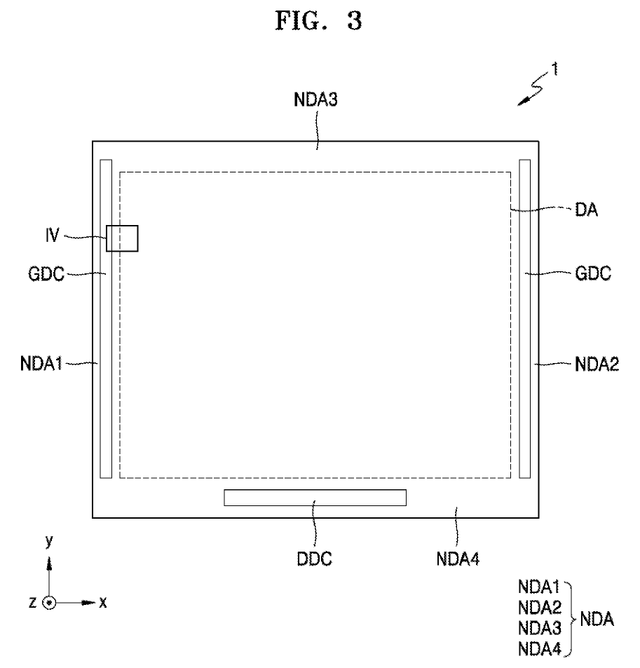

FIG. 3 is a plan view schematically illustrating a display device 1 according to an embodiment.

A plurality of pixels may be disposed in a display area DA of the display device 1. The pixels may each include sub-pixels configured to emit light of different (or various) colors. Light-emitting elements respectively corresponding to the sub-pixels may be disposed in the display area DA. A circuit configured to provide electrical signals to the light-emitting elements disposed in the display area DA and transistors electrically connected to the light-emitting elements may be disposed in the non-display area NDA surrounding the display area DA. Gate driving circuits GDC may be respectively disposed in a first non-display area NDA1 and a second non-display area NDA2, which are respectively on both sides of the display area DA. The gate driving circuit GDC may include drivers configured to provide electrical signals to gate electrodes of the transistors electrically connected to the light-emitting elements. Although FIG. 3 illustrates an embodiment in which the gate driving circuits GDC are respectively disposed in the first non-display area NDA1 and the second non-display area NDA2, the present disclosure is not limited thereto. In another embodiment, the gate driving circuit GDC may be disposed in either the first non-display area NDA1 or the second non-display area NDA2.

A data driving circuit DDC may be disposed in a third non-display area NDA3 and/or a fourth non-display area NDA4, which connects (or extends between) the first non-display area NDA1 to the second non-display area NDA2. FIG. 3 illustrates an embodiment in which the data driving circuit DDC is disposed in the fourth non-display area NDA4. In another embodiment, data driving circuits DDC may be respectively disposed in the third non-display area NDA3 and the fourth non-display area NDA4.

Although the embodiment illustrated in FIG. 3 includes the data driving circuit DDC disposed in the fourth non-display area NDA4 of the display device 1, the present disclosure is not limited thereto. In another embodiment, the display device 1 may further include a flexible circuit board electrically connected through a terminal portion disposed in the fourth non-display area NDA4, and the data driving circuit DDC may be disposed on the flexible circuit board.

In some embodiments, the elongation rate of the non-display area NDA may be less than or equal to the elongation rate of the display area DA. In an embodiment, the elongation rate of the non-display area NDA may be different for each area. For example, the first non-display area NDA1, the second non-display area NDA2, and the third non-display area NDA3 may have substantially the same elongation rate, but the elongation rate of the fourth non-display area NDA4 may be less than the elongation rate of each of the first non-display area NDA1, the second non-display area NDA2, and the third non-display area NDA3.

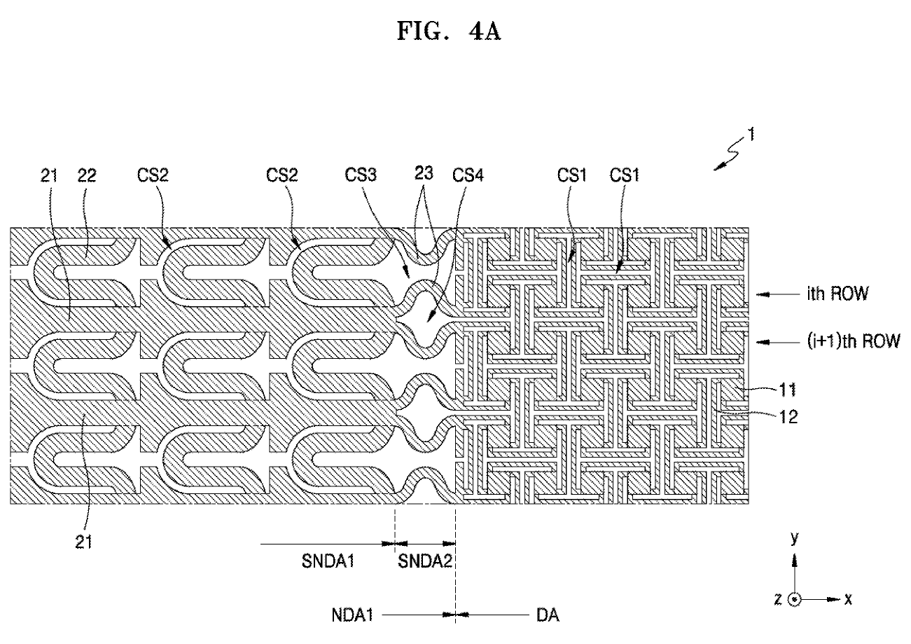

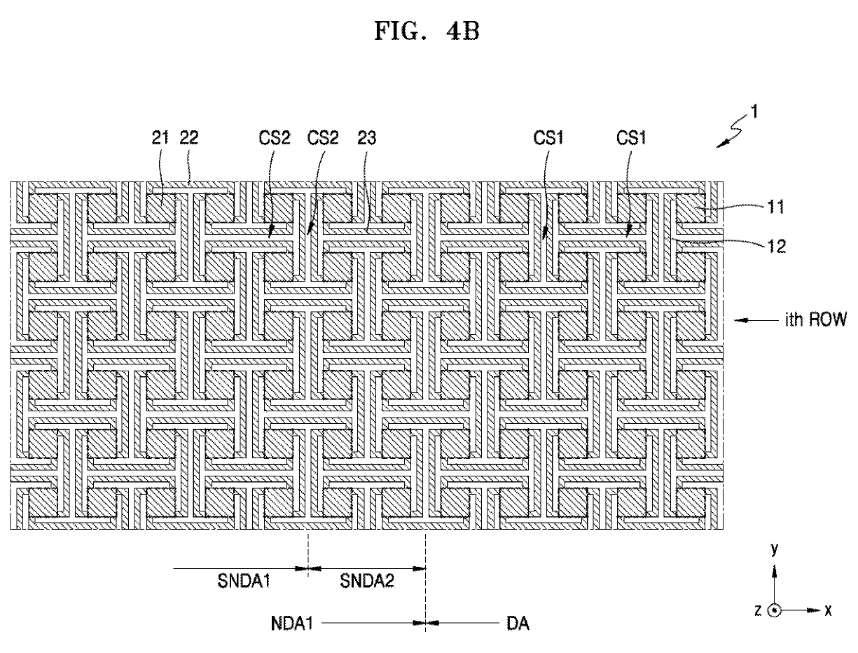

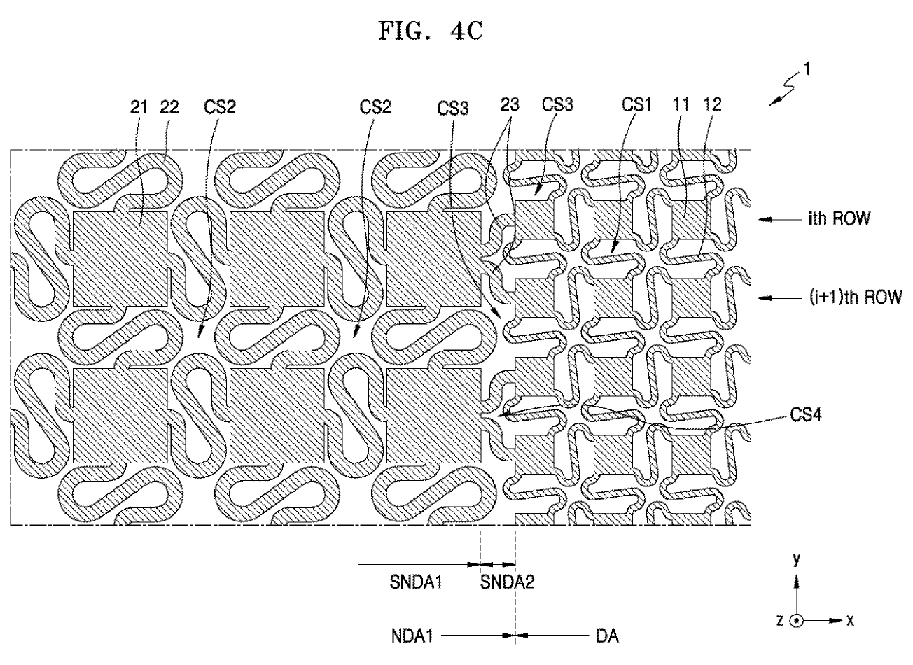

FIG. 4A is an enlarged plan view of the region IV in FIG. 3 as a portion of the display device 1 according to an embodiment.

Referring to FIG. 4A, the display device 1 may include first island portions 11 spaced apart from each other in the first direction (e.g., the +x direction or the -x direction) and the second direction (e.g., the +y direction or the -y direction) in the display area DA and first bridge portions 12 connecting adjacent ones of the first island portions 11 to each other.

Each of the first island portions 11 may be connected to a plurality of first bridge portions 12. For example, each of the first island portions 11 may be connected to four first bridge portions 12. The two first bridge portions 12 may be respectively disposed on both sides of the first island portion 11 in the first direction (e.g., the +x direction or the -x direction), and the remaining two first bridge portions 12 may be respectively disposed on both sides of the first island portion 11 in the second direction (e.g., the +y direction or the -y direction). In an embodiment, the four first bridge portions 12 may be respectively connected to four sides of the first island portion 11. The four first bridge portions 12 may be respectively adjacent to corners of the first island portion 11.

The first bridge portions 12 may be spaced apart from each other by a first opening CS1 between adjacent ones of the first bridge portions 12. In an embodiment, a first opening CS1 having an approximately H shape and a first opening CS1 having an approximately I-shape obtained by rotating the H-shape by 90 degrees may be alternately and repeatedly disposed in the first direction (e.g., the +x direction or the -x direction) and the second direction (e.g., the +y direction or the -y direction). Both end portions of each of the first bridge portions 12 may be respectively connected to the adjacent first island portions 11, and one side of each of the first bridge portions 12 may be spaced apart from one side of the adjacent first island portion 11 and/or one side of another first bridge portion 12 by the first opening CS1.

The display device 1 may include second island portions 21 spaced apart from each other and second bridge portions 22 connecting adjacent ones of the second island portions 21 to each other in the non-display area, for example, in the first non-display area NDA1 illustrated in FIG. 4A.

Each of the second island portions 21 may extend in the first direction (e.g., the +x direction or the -x direction). The second island portions 21 may be spaced apart from each other in the second direction (e.g., the +y direction or the -y direction) crossing the first direction (e.g., the +x direction or the -x direction). The second island portions 21 may include drivers of the gate driving circuits (see, e.g., GDC in FIG. 3) described with reference to FIG. 3, respectively.

The second bridge portion 22 may have a serpentine shape. The length of the second bridge portion 22 may be greater than the shortest distance between the adjacent second island portions 21 in the second direction (e.g., the +y direction or the -y direction). In an embodiment, the second bridge portion 22 may have an approximately omega (Ω) shape that is convex in the first direction (e.g., the +x direction or the -x direction). The second bridge portions 22 may be disposed between the adjacent second island portions 21 and may be spaced apart from each other.

The second bridge portions 22 between the adjacent second island portions 21 may be spaced apart from each other by the second opening CS2. The second openings CS2 and the second bridge portions 22 may be alternately disposed in the first direction (e.g., the +x direction or the -x direction) between adjacent ones of the second island portions 21. The second openings CS2 may have the same shape. Both end portions of each of the second bridge portions 22 may be connected to the adjacent second island portions 21, and one side of each of the second bridge portions 22 may be spaced apart from one side of the adjacent second island portion 21 and/or one side of another second bridge portion 22 by the second opening CS2.

One second island portion 21 disposed in the first non-display area NDA1 may correspond to a plurality of rows of first island portions 11 disposed in the display area DA. For example, one second island portion 21 disposed in the first non-display area NDA1 may correspond to first island portions 11 disposed in an i^{th} row and first island portions 11 disposed in an (i+1)^{th} row in the display area DA (where i is a positive number greater than 0). Although FIG. 4A illustrates an embodiment in which one second island portion 21 corresponds to two rows of the first island portions 11, the present disclosure is not limited thereto. In another embodiment, one second island portion 21 disposed in the first non-display area NDA1 may correspond to n rows of the first island portions 11 disposed in the display area DA (where n is a positive number greater than or equal to 3).

The non-display area, for example, the first non-display area NDA1, may include a first sub-non-display area SNDA1 in which the second island portions 21 and the second bridge portions 22 are disposed and a second sub-non-display area SNDA2 between the first sub-non-display area SNDA1 and the display area DA. Third bridge portions 23 may be disposed in the second sub-non-display area SNDA2 to connect the display area DA to the first sub-non-display area SNDA1. One end portion of the third bridge portion 23 may be connected to the second island portion 21 and/or the second bridge portion 22, and the other end portion of the third bridge portion 23 may be connected to the first island portion 11 and/or the first bridge portion 12.

The third bridge portion 23 may have a serpentine shape. In an embodiment, the shape of the third bridge portion 23 may be different from the shape of the first bridge portion 12 and the shape of the second bridge portion 22. In the embodiment illustrated in FIG. 4A, the third bridge portion 23 may have an approximately omega (Ω) shape that is convex in the second direction (e.g., the +y direction or the -y direction). The third bridge portions 23 may have a symmetrical structure in which one of the adjacent third bridge portions 23 disposed in the second direction (e.g., the +y direction or the -y direction) is convex in the +y direction and the other thereof is convex in the -y direction. The third openings CS3 and the fourth openings CS4 having different shapes from each other may be repeated between the third bridge portions 23. The width of the third bridge portion 23 may be different from the width of the first bridge portion 12 and the width of the second bridge portion 22. In an embodiment, the width of the third bridge portion 23 may be greater than the width of the first bridge portion 12 and less than the width of the second bridge portion 22.

FIG. 4A illustrates an embodiment in which the second island portion 21 and the second bridge portion 22 in the non-display area, for example, the first non-display area NDA1, have different shapes from the first island portion 11 and the first bridge portion 12 in the display area DA. In another embodiment, the second island portion 21 and the second bridge portion 22 in the non-display area may have the same shape as the first island portion 11 and the first bridge portion 12 in the display area DA, respectively.

FIG. 4B is an enlarged plan view of the region IV in FIG. 3 as a portion of the display device 1 according to another embodiment.

Referring to FIG. 4B, the display device 1 may include first island portions 11 spaced apart from each other in the display area DA, and first bridge portions 12 spaced apart from each other by first openings CS1 and connecting adjacent ones of the first island portions 11 to each other. The structure of the display area DA shown in FIG. 4B may be the same as the structure of the display area DA described above with reference to FIG. 4A.

The display device 1 may include second island portions 21 and second bridge portions 22 disposed in a non-display area, for example, a first non-display area NDA1. In an embodiment, the second island portions 21 and the second bridge portions 22 may have substantially the same shape as the first island portions 11 and the first bridge portions 12, respectively.

The second island portions 21 may be spaced apart from each other in the first direction (e.g., the +x direction or the -x direction) and the second direction (e.g., the +y direction or the -y direction) in the non-display area, for example, the first non-display area NDA1. The second bridge portions 22 may each connect adjacent ones of the second island portions 21 to each other. The second bridge portions 22 may be spaced apart from each other by the second opening CS2 between the second bridge portions 22.

The second opening CS2 may have substantially the same shape as the first opening CS1. For example, the second opening CS2 having an approximately H-shape and the second opening CS2 having an approximately I-shape may be alternately and repeatedly disposed in the non-display area, for example, the first non-display area NDA1. Both end portions of each of the second bridge portions 22 may be connected to the adjacent second island portions 21, and one side of each of the second bridge portions 22 may be spaced apart from one side of the adjacent second island portion 21 and/or one side of another second bridge portion 22 by the second opening CS2.

Each of the second island portions 21 may be connected to four second bridge portions 22. The second island portions 21 may include drivers of the gate driving circuit (see, e.g., GDC in FIG. 3) described above with reference to FIG. 3.

One row of the second island portions 21 disposed in the first non-display area NDA1 may correspond to one row of the first island portions 11 disposed in the display area DA1. For example, the second island portions 21 disposed in the i^{th} row in the first direction (e.g., the +x direction or the -x direction) in the first non-display area NDA1 may correspond to the first island portions 11 disposed in the same row, for example, the i^{th} row, in the display area DA (where i is a positive number greater than 0).

The display device 1 may include third bridge portions 23 disposed in the second sub-non-display area SNDA2 to connect the display area DA to the first sub-non-display area SNDA1. The non-display area, for example, the first non-display area NDA1, may include a first sub-non-display area SNDA1 in which the second island portions 21 and the second bridge portions 22 are disposed and a second sub-non-display area SNDA2 between the first sub-non-display area SNDA1 and the display area DA and including the third bridge portions 23. The third bridge portion 23 may be substantially the same as the first bridge portion 12 and the second bridge portion 22. For example, the width of the third bridge portion 23 may be the same as the width of the first bridge portion 12 and the width of the second bridge portion 22.

FIG. 4C is an enlarged plan view of the region IV in FIG. 3 as a portion of the display device 1 according to another embodiment.

Referring to FIG. 4C, the display device 1 may include first island portions 11 spaced apart from each other in the first direction (e.g., the +x direction or the -x direction) and the second direction (e.g., the +y direction or the -y direction) in a display area DA and first bridge portions 12 connecting adjacent ones of the first island portions 11 to each other.

The first bridge portions 12 may be spaced apart from each other by a first opening CS1 between the first bridge portions 12. The first bridge portion 12 may have a serpentine shape. For example, as illustrated in FIG. 4C, the first bridge portion 12 may have an approximately S shape.

Each of the first island portions 11 may be connected to a plurality of first bridge portions 12. For example, each of the first island portions 11 may be connected to four first bridge portions 12. The two first bridge portions 12 may be respectively disposed on both sides of the first island portion 11 in the first direction (e.g., the +x direction or the -x direction), and the remaining two first bridge portions 12 may be respectively disposed on both sides of the first island portion 11 in the second direction (e.g., the +y direction or the -y direction). The four first bridge portions 12 may be respectively connected to four sides of the first island portion 11. The four first bridge portions 12 may be respectively adjacent to corners of the first island portion 11.

The display device 1 may include second island portions 21 spaced apart from each other in the first direction (e.g., the +x direction or the -x direction) and the second direction (e.g., the +y direction or the -y direction) in the non-display area, for example, the first non-display area NDA1 as illustrated in FIG. 4C, and second bridge portions 22 connecting adjacent ones of the second island portions 21 to each other.

The second bridge portions 22 may be spaced apart from each other by a second opening CS2 between the second bridge portions 22. The second bridge portion 22 may have a serpentine shape. For example, as illustrated in FIG. 4C, the second bridge portion 22 may have an approximately S shape. The size and/or width of the second bridge portion 22 may be different from the size and/or width of the first bridge portion 12. For example, the size and/or width of the second bridge portion 22 may be greater than the size and/or width of the first bridge portion 12. The radius of curvature of the round portion of the second bridge portion 22 may be different from the radius of curvature of the round portion of the first bridge portion 12. For example, the radius of curvature of the round portion of the second bridge portion 22 may be greater than the radius of curvature of the round portion of the first bridge portion 12.

Each of the second island portions 21 may be connected to a plurality of second bridge portions 22. Each of the second island portions 21 may be connected to four second bridge portions 22. The two second bridge portions 22 may be respectively disposed on both sides of the second island portion 21 in the first direction (e.g., the +x direction or the -x direction), and the remaining two second bridge portions 22 may be respectively disposed on both sides of the second island portion 21 in the second direction (e.g., the +y direction or the -y direction). In an embodiment, the four second bridge portions 22 may be respectively connected to four sides of the second island portion 21. The four second bridge portions 22 may be respectively connected to the central portions of the four sides of the second island portion 21.

One row of the second island portions 21 disposed in the first non-display area NDA1 may correspond to a plurality of rows of the first island portions 11 disposed in the display area DA1. For example, one row of the second island portions 21 disposed in the first non-display area NDA1 may correspond to first island portions 11 disposed in an i^{th} row and first island portions 11 disposed in an (i+1)^{th} row in the display area DA (where i is a positive number greater than 0). In another embodiment, one row of the second island portions 21 may correspond to n rows of the first island portions 11 (where n is a positive number greater than or equal to 3).

The non-display area, for example, the first non-display area NDA1, may include a first sub-non-display area SNDA1 in which the second island portions 21 and the second bridge portions 22 are disposed and a second sub-non-display area SNDA2 between the first sub-non-display area SNDA1 and the display area DA. Third bridge portions 23 may be disposed in the second sub-non-display area SNDA2 to connect the display area DA to the first sub-non-display area SNDA1. One end portion of the third bridge portion 23 may be connected to the second island portion 21, and the other end portion of the third bridge portion 23 may be connected to the first island portion 11. For example, one end portion of the third bridge portion 23 may be connected to the central portion of one side of the second island portion 21, and the other end portion of the third bridge portion 23 may be connected to the central portion of one side of the first island portion 11.

The third bridge portion 23 may have a serpentine shape. In an embodiment, the shape of the third bridge portion 23 may be different from the shape of the first bridge portion 12 and the shape of the second bridge portion 22. The width of the third bridge portion 23 may be different from the width of the first bridge portion 12 and the width of the second bridge portion 22. The width of the third bridge portion 23 may be greater than the width of the first bridge portion 12 and less than the width of the second bridge portion 22. Third openings CS3 and fourth openings CS4 having different shapes may be alternately disposed between the third bridge portions 23 in the second direction (e.g., the +y direction or the -y direction).

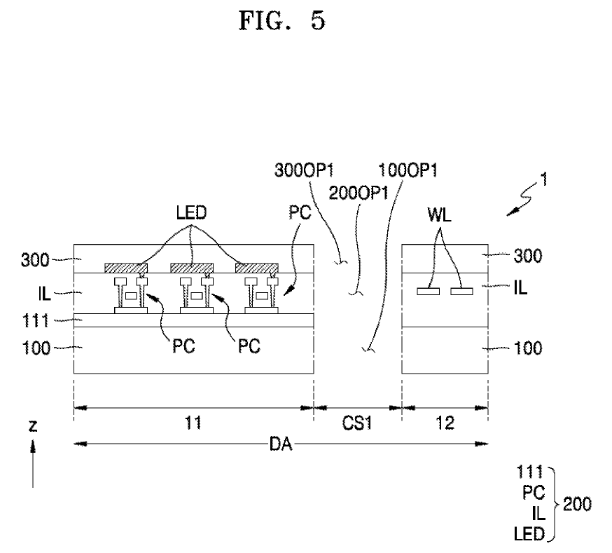

FIG. 5 is a cross-sectional view schematically illustrating the first island portion 11 and the first bridge portion 12, which are disposed in the display area DA of the display device 1, according to an embodiment.

Referring to FIG. 5, the first island portion 11 and the first bridge portion 12 in the display area DA may be spaced apart from each other with the first opening CS1 therebetween. The first island portion 11 may include light-emitting elements LED and a circuit configured to drive the light-emitting elements electrically connected thereto, such as pixel driving circuits PC. The first bridge portion 12 may include wirings WL electrically connected to the pixel driving circuits PC respectively disposed in the adjacent first island portions 11.

In the first island portion 11, a buffer layer 111 including an inorganic insulating material may be disposed on a substrate 100, and the pixel driving circuits PC may be disposed on the buffer layer 111. An insulating layer IL including an inorganic insulating material and/or an organic insulating material may be disposed between the pixel driving circuits PC and the light-emitting elements LED. The light-emitting element LED may be disposed on the insulating layer IL and may be electrically connected to the corresponding pixel driving circuit PC. The light-emitting elements LED may be configured to emit light of different (or various) colors or the same color. In an embodiment, the light-emitting elements LED may be configured to emit (e.g., externally emit) red light, green light, and blue light. In some embodiments, the light-emitting elements LED may be configured to emit white light. In another embodiment, the light-emitting elements LED may be configured to emit red light, green light, blue light, and white light.

The substrate 100 may include polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate, or propionate. In an embodiment, the substrate 100 may be a single layer including the polymer resin described above. In another embodiment, the substrate 100 may have a multilayer structure including a base layer and a barrier layer. The base layer may include the polymer resin described above and the barrier layer may include an inorganic insulating material. The substrate 100 including the polymer resin may be flexible, rollable, or bendable.

Although FIG. 5 illustrates an embodiment in which three pixel driving circuits PC are disposed in each of the first island portions 11 and three light-emitting elements LED are respectively connected to the three pixel driving circuits PC, the present disclosure is not limited thereto. In another embodiment, the number of pixel driving circuits PC and light-emitting elements LED disposed in the first island portion 11 may be one, two, or four or more.

An encapsulation layer 300 may be disposed on the light-emitting elements LED and may protect the light-emitting elements LED from an external force and/or moisture penetration. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked in this order. In another embodiment, the encapsulation layer 300 may include an organic material, such as resin. In some embodiments, the encapsulation layer 300 may include urethane epoxy acrylate. The encapsulation layer 300 may include a photosensitive material, such as a photoresist.

In the first bridge portion 12, an insulating layer IL including an organic insulating material may be disposed on the substrate 100. The first bridge portion 12, which is deformed relatively greatly when the display device 1 is stretched, may not have a layer including an inorganic insulating material that is prone to cracks, unlike the first island portion 11.

In an embodiment, the substrate 100 corresponding to the first bridge portion 12 may have the same stack structure as the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a different stack structure from the substrate 100 corresponding to the first island portion 11. In some embodiments, the substrate 100 corresponding to the first island portion 11 may have a multilayer structure including a base layer including polymer resin and a barrier layer including an inorganic insulating material, and the substrate 100 corresponding to the first bridge portion 12 may have a structure of a polymer resin layer without (or omitting) a layer including an inorganic insulating material.

As described above, the wirings WL of the first bridge portion 12 may include a signal line (e.g., a gate line, a data line, etc.) configured to provide an electrical signal to the transistor included in the pixel driving circuit PC of the first island portion 11 or may include a voltage line (e.g., a driving voltage line, an initialization voltage line, etc.) configured to provide a voltage to the transistor included in the pixel driving circuit PC of the first island portion 11. The encapsulation layer 300 may also be disposed on the first bridge portion 12. In another embodiment, the encapsulation layer 300 may not be present in the first bridge portion 12.

Referring to FIGS. 4A to 4C and 5, the substrate 100 corresponding to the first island portion 11 and the substrate 100 corresponding to the first bridge portion 12 may be connected to each other. For example, the plan views illustrated in FIGS. 4A to 4C may be substantially the same as the plan view of the substrate 100 shown in FIG. 5. In other words, the substrate 100 may have an area corresponding to the first island portion 11, an area corresponding to the first bridge portion 12, and an opening 100OP1 having the same shape as the first opening CS1.

Similarly, the encapsulation layer 300 corresponding to the first island portion 11 and the encapsulation layer 300 corresponding to the first bridge portion 12 may be connected to each other. For example, the plan views illustrated in FIGS. 4A to 4C may be substantially the same as the plan view of the encapsulation layer 300. In other words, the encapsulation layer 300 may have an area corresponding to the first island portion 11, an area corresponding to the first bridge portion 12, and an opening 300OP1 having the same shape as the first opening CS1.

A circuit light-emitting element layer 200 between the substrate 100 and the encapsulation layer 300 may include a buffer layer 111, a pixel driving circuit PC, a wiring WL, an insulating layer IL, and a light-emitting element LED. Similar to the substrate 100, the plan views illustrated in FIGS. 4A to 4C may be substantially the same as the plan view of the circuit light-emitting element layer 200. In other words, the circuit light-emitting element layer 200 may have an opening 200OP1 having the same shape as the first opening CS1.

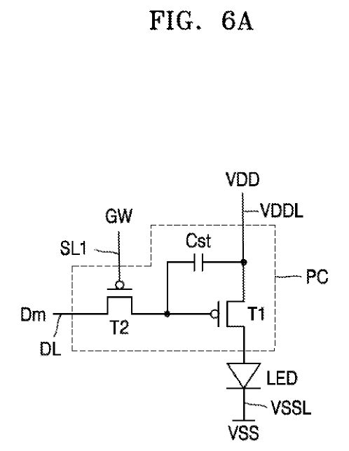

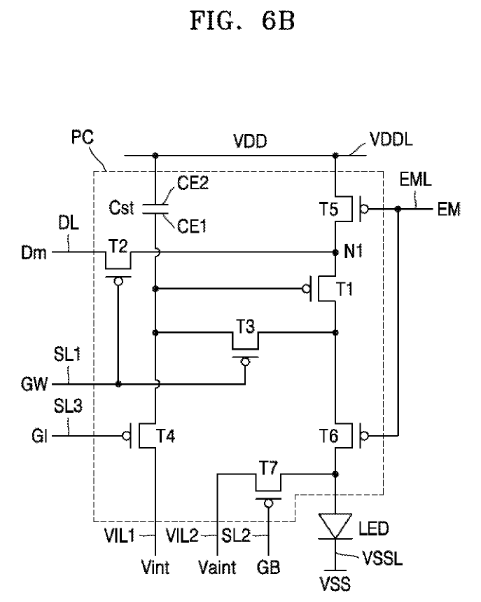

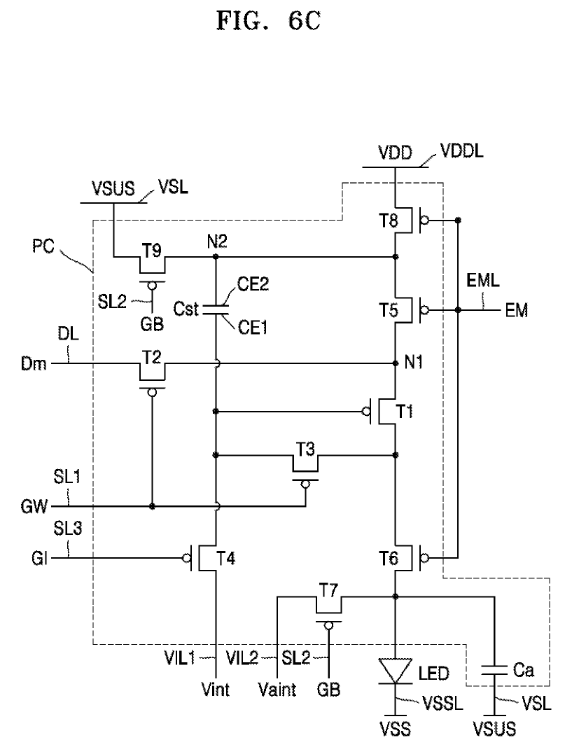

FIGS. 6A to 6C are equivalent circuit diagrams of a sub-pixel of a display device (see 1 of FIG. 1), according to an embodiment.

Referring to FIG. 6A, a light-emitting element LED corresponding to the sub-pixel may be electrically connected to a pixel driving circuit PC. The pixel driving circuit PC may include a first transistor T1, a second transistor T2, and a storage capacitor Cst. The pixel driving circuit PC may be electrically connected to signal lines and voltage lines. The signal lines may include a gate line, such as a first scan line SL1, and a data line DL. The voltage lines may include a first voltage line VDDL.

The second transistor T2 may be electrically connected to the first scan line SL1 and the data line DL. The first scan line SL1 may be configured to provide a first scan signal GW1 to a gate electrode of the second transistor T2. The second transistor T2 may be configured to transmit, to the first transistor T1, a data signal Dm input from the data line DL, in response to the first scan signal GW1 input from the first scan line SL1.

The storage capacitor Cst may be electrically connected to the second transistor T2 and the first voltage line VDDL and may be configured to store a voltage corresponding to a difference between a voltage received from the second transistor T2 and a first power supply voltage VDD supplied through the first voltage line VDDL.

The first transistor T1, which acts as a driving transistor, may be configured to control a driving current flowing through the light-emitting element LED. The first transistor T1 may be connected to the first voltage line VDDL and the storage capacitor Cst. The first transistor T1 may be configured to control the driving current flowing from the first voltage line VDDL to the light-emitting element LED according to a voltage value stored in the storage capacitor Cst. The light-emitting element LED may be configured to emit light having a certain luminance according to the driving current. A first electrode of the light-emitting element LED may be electrically connected to the first transistor T1, and a second electrode of the light-emitting element LED may be electrically connected to a second voltage line VSSL configured to supply a second power supply voltage VSS.

FIG. 6A illustrates an embodiment in which the pixel driving circuit PC includes two transistors and one storage capacitor, but in another embodiment, the pixel driving circuit PC may include three or more transistors.

Referring to FIG. 6B, the pixel driving circuit PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit PC may be electrically connected to signal lines and voltage lines. The signal lines may include a data line DL and gate lines, such as a first scan line SL1, a second scan line SL2, a third scan line SL3, a fourth scan line SL4, and an emission control line EML. The voltage lines may include first and second initialization voltage lines VIL1 and VIL2 and a first voltage line VDDL.

The first voltage line VDDL may be configured to transmit a first power supply voltage VDD to the first transistor T1. The first initialization voltage line VIL1 may be configured to transmit, to the pixel driving circuit PC, a first initialization voltage Vint for initializing the first transistor T1. The second initialization voltage line VIL2 may be configured to transmit, to the pixel driving circuit PC, a second initialization voltage Vaint for initializing a first electrode of a light-emitting element LED.

The first transistor T1 may be electrically connected to the first voltage line VDDL via the fifth transistor T5 and may be electrically connected to the light-emitting element LED via the sixth transistor T6. The first transistor T1, which acts as a driving transistor, may be configured to receive a data signal Dm according to the switching operation of the second transistor T2 and supply a driving current to the light-emitting element LED.

The second transistor T2, which acts as a data write transistor, may be electrically connected to the first scan line SL1 and the data line DL. The second transistor T2 may be electrically connected to the first voltage line VDDL via the fifth transistor T5. The second transistor T2 may be configured to be turned on in response to a first scan signal GW received through the first scan line SL1 to perform a switching operation to transmit the data signal Dm received through the data line DL to a first node N1.

The third transistor T3 may be electrically connected to the first scan line SL1 and electrically connected to the light-emitting element LED via the sixth transistor T6. The third transistor T3 may be configured to be turned on in response to the first scan signal GW received through the first scan line SL1 to diode-connect the first transistor T1.

The fourth transistor T4, which acts as a first initialization transistor, may be electrically connected to the third scan line SL3 and the first initialization voltage line VIL1. The fourth transistor T4 may be configured to be turned on in response to a third scan signal GI received through the third scan line SL3 to initialize the voltage of the gate electrode of the first transistor T1 by transmitting the first initialization voltage Vint from the first initialization voltage line VIL1 to the gate electrode of the first transistor T1. The third scan signal GI may correspond to the first scan signal of another pixel driving circuit disposed in the previous row of the corresponding pixel driving circuit PC.

The fifth transistor T5 may act as an operation control transistor, and the sixth transistor T6 may act as an emission control transistor. The fifth transistor T5 and the sixth transistor T6 may be electrically connected to the emission control line EML and may be configured to be concurrently (or simultaneously) turned on in response to an emission control signal EM received through the emission control line EML to form a current path through which the driving current flows in a direction from the first voltage line VDDL to the light-emitting element LED.

The seventh transistor T7, which acts as a second initialization transistor, may be electrically connected to the second scan line SL2, the second initialization voltage line VIL2, and the sixth transistor T6. The seventh transistor T7 may be configured to be turned on in response to a second scan signal GB received through the second scan line SL2 to initialize the first electrode of the light-emitting element LED by transmitting the second initialization voltage Vaint from the second initialization voltage line VIL2 to the first electrode of the light-emitting element LED.

The storage capacitor Cst may include a first electrode CE1 and a second electrode CE2. The first electrode CE1 may be electrically connected to the gate electrode of the first transistor T1 and the second electrode CE2 may be electrically connected to the first voltage line VDDL. The storage capacitor Cst may store and maintain a voltage corresponding to a voltage difference between the first voltage line VDDL and the gate electrode of the first transistor T1, and thus, the voltage applied to the gate electrode of the first transistor T1 may be maintained.

Referring to FIG. 6C, a pixel driving circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit PC may be electrically connected to signal lines and voltage lines. The signal lines may include a data line DL and gate lines, such as a first scan line SL1, a second scan line SL2, a third scan line SL3, a fourth scan line SL4, and an emission control line EML. The voltage lines may include first and second initialization voltage lines VIL1 and VIL2, a sustain voltage line VSL, and a first voltage line VDDL.

The first voltage line VDDL may be configured to transmit a first power supply voltage VDD to the first transistor T1. The first initialization voltage line VIL1 may be configured to transmit, to the pixel driving circuit PC, a first initialization voltage Vint for initializing the first transistor T1. The second initialization voltage line VIL2 may be configured to transmit, to the pixel driving circuit PC, a second initialization voltage Vaint for initializing a first electrode of a light-emitting element LED. The sustain voltage line VSL may be configured to provide a sustain voltage VSUS to a second node N2, for example, a second electrode CE2 of the storage capacitor Cst, in an initialization period and a data write period.

The first transistor T1 may be electrically connected to the first voltage line VDDL via the fifth transistor T5 and the eighth transistor T8 and may be electrically connected to the light-emitting element LED via the sixth transistor T6. The first transistor T1, which acts as a driving transistor, may be configured to receive a data signal Dm according to the switching operation of the second transistor T2 and to supply a driving current to the light-emitting element LED.

The second transistor T2 may be electrically connected to the first scan line SL1 and the data line DL and electrically connected to the first voltage line VDDL via the fifth transistor T5 and the eighth transistor T8. The second transistor T2 may be configured to be turned on in response to a first scan signal GW received through the first scan line SL1 to perform a switching operation to transmit, to a first node N1, the data signal Dm transmitted through the data line DL.

The third transistor T3 may be electrically connected to the first scan line SL1 and electrically connected to the light-emitting element LED via the sixth transistor T6. The third transistor T3 may be configured to be turned on in response to the first scan signal GW received through the first scan line SL1 to compensate for a threshold voltage of the first transistor T1 by diode-connecting the first transistor T1.

The fourth transistor T4 may be electrically connected to the third scan line SL3 and the first initialization voltage line VIL1 and may be configured to be turned on in response to a third scan signal GI received through the third scan line SL3 to initialize the voltage of the gate electrode of the first transistor T1 by transmitting the first initialization voltage Vint from the first initialization voltage line VIL1 to the gate electrode of the first transistor T1. The third scan signal GI may correspond to the first scan signal of another pixel driving circuit arranged in the previous row of the corresponding pixel driving circuit PC.

The fifth transistor T5, the sixth transistor T6, and the eighth transistor T8 may be electrically connected to the emission control line EML and may be configured to be concurrently (or simultaneously) turned on in response to an emission control signal EM received through the emission control line EML to form a current path through which the driving current flows in a direction from the first voltage line VDDL to the light-emitting element LED.

The seventh transistor T7, which acts as a second initialization transistor, may be electrically connected to the second scan line SL2, the second initialization voltage line VIL2, and the sixth transistor T6. The seventh transistor T7 may be configured to be turned on in response to a second scan signal GB received through the second scan line SL2 to initialize the first electrode of the light-emitting element LED by transmitting the second initialization voltage Vaint from the second initialization voltage line VIL2 to the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be configured to be turned on in response to the second scan signal GB received through the second scan line SL2 to transmit the sustain voltage VSUS to the second node N2, for example, the second electrode CE2 of the storage capacitor Cst, in the initialization period and the data write period.

The eighth transistor T8 and the ninth transistor T9 may be electrically connected to the second scan line N2, for example, the second electrode CE2 of the storage capacitor Cst. In some embodiments, in the initialization period and the data write period, the eighth transistor T8 may be turned off and the ninth transistor T9 may be turned on, and in the emission period, the eighth transistor T8 may be turned on and the ninth transistor T9 may be turned off. Because the sustain voltage VSUS is transmitted to the second node N2 in the initialization period and the data write period, the luminance uniformity (e.g., long range uniformity (LRU)) of the display device according to the voltage drop of the first voltage line VDDL may be improved.

The storage capacitor Cst may include a first electrode CE1 and a second electrode CE2. The first electrode CE1 of the storage capacitor Cst may be electrically connected to the gate electrode of the first transistor T1, and the second electrode CE2 of the storage capacitor Cst may be electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may store and maintain a voltage corresponding to a voltage difference between the first electrode of the light-emitting element LED and the sustain voltage line VSL while the seventh transistor T7 and the ninth transistor T9 are turned on, and thus, an increase in black luminance when the sixth transistor T6 is turned off may be mitigated or prevented.

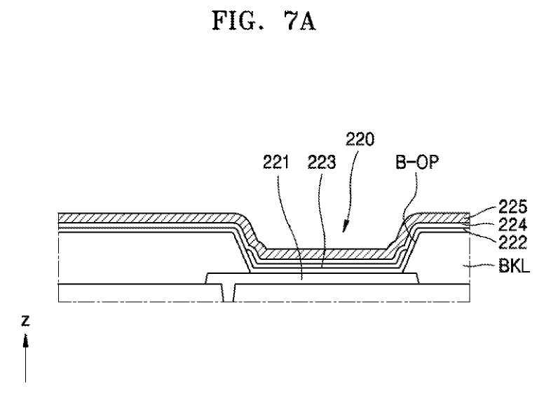

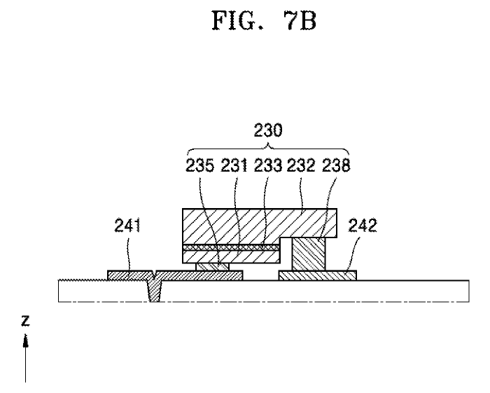

FIG. 7A is a cross-sectional view schematically illustrating a light-emitting element of a display device (see, e.g., 1 in FIG. 1) according to an embodiment.

Referring to FIG. 7A, the light-emitting element according to an embodiment may include an organic light-emitting diode 220 including an organic material. The organic light-emitting diode 220 may include a first electrode 221 disposed on an insulating layer, a second electrode 225 facing the first electrode 221, and an emission layer 223 between the first electrode 221 and the second electrode 225. A first functional layer 222 may be disposed between the first electrode 221 and the emission layer 223, and a second functional layer 224 may be disposed between the emission layer 223 and the second electrode 225.

An edge of the first electrode 221 may be covered by a bank layer BKL including an insulating material. The bank layer BKL may have an opening B-OP overlapping (e.g., aligned with) the central portion of the first electrode 221.

The first electrode 221 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the first electrode 221 may be (or may include) a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In another embodiment, the first electrode 221 may further include a layer including ITO, IZO, ZnO, AZO, or In₂O₃ above and/or below the reflective layer.

The emission layer 223 may include a high molecular weight organic material or a low molecular weight organic material that emits light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. For example, the second electrode 225 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. In another embodiment, the second electrode 225 may further include a layer including ITO, IZO, ZnO, AZO, or In₂O₃ on the (semi)transparent layer including the material described above.

FIG. 7B is a cross-sectional view schematically illustrating a light-emitting element of a display device (see, e.g., 1 in FIG. 1) according to another embodiment.

Referring to FIG. 7B, the light-emitting element according to an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242, which are disposed on the same layer.

In some embodiments, the first semiconductor layer 231 may include a p-type semiconductor layer. The p-type semiconductor layer may be selected from semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, or AlInN, and may be doped with a p-type dopant, such as Mg, Zn, Ca, Sr, or Ba.

The second semiconductor layer 232 may include, for example, an n-type semiconductor layer. The n-type semiconductor layer may be selected from semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, or AlInN, and may be doped with an n-type dopant, such as Si, Ge, or Sn.

The intermediate layer 233 is an area (or layer) where electrons and holes recombine. As the electrons and the holes recombine, the intermediate layer 233 may transition to a low energy level to generate light having a wavelength corresponding thereto. For example, the intermediate layer 233 may include a semiconductor material having a composition formula of InₓAl_{y}Ga_{1-x-y}N (0≤x≤1, 0≤y≤1, 0≤x+y≤1) and may have a single quantum well structure or a multi quantum well (MQW) structure. In addition, the intermediate layer 233 may have a quantum wire structure or a quantum dot structure.

Although FIG. 7B illustrates an embodiment in which the first semiconductor layer 231 includes a p-type semiconductor layer and the second semiconductor layer 232 includes an n-type semiconductor layer, the present disclosure is not limited thereto. In another embodiment, the first semiconductor layer 231 may include an n-type semiconductor layer, and the second semiconductor layer 232 may include a p-type semiconductor layer.

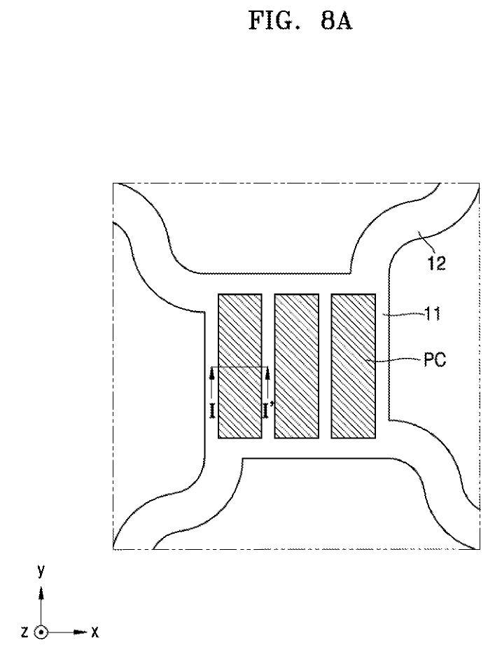

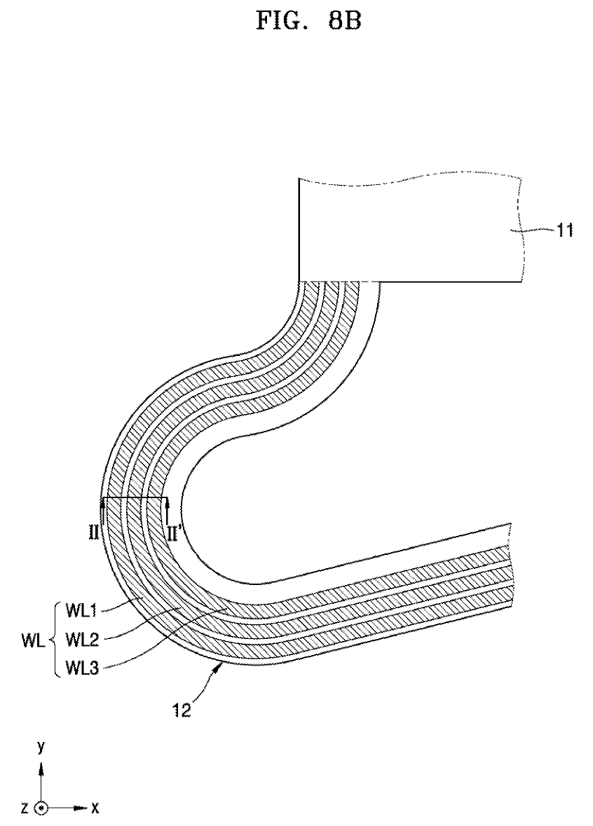

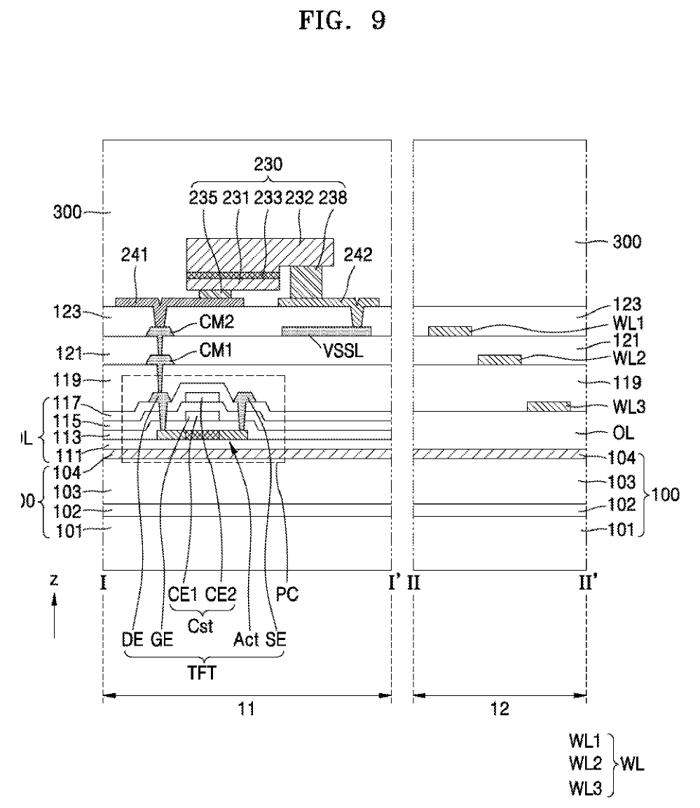

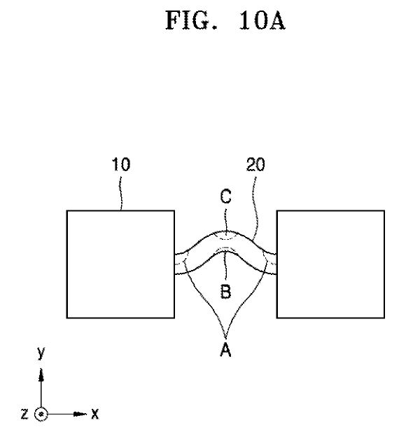

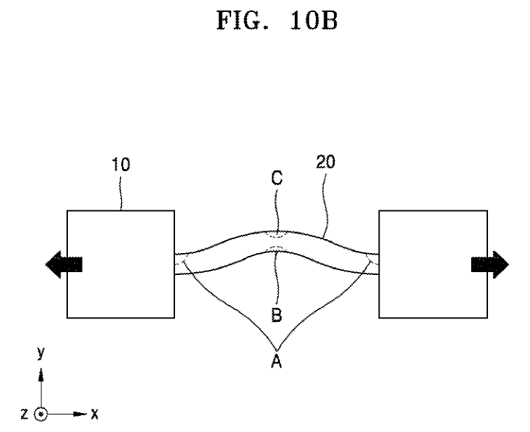

FIG. 8A is an enlarged plan view of the first island portion 11 of the display device (see, e.g., 1 in FIG. 1) according to an embodiment, and FIG. 8B is a plan view illustrating the layout of the wirings WL on the first bridge portion 12 of the display device (see, e.g., 1 in FIG. 1) according to an embodiment. In addition, FIG. 9 illustrates a cross-section taken along the line I-I’ in FIG. 8A and a cross-section taken along the line II-II’ in FIG. 8B.

Referring to FIG. 8A, the first island portion 11 disposed in the display area DA may include a light-emitting element and a pixel driving circuit PC electrically connected thereto. The pixel driving circuit PC may include transistors and at least one capacitor, as described above. Although FIG. 8A illustrates an embodiment in which three pixel driving circuits PC are disposed in the first island portion 11, the present disclosure is not limited thereto. In another embodiment, the number of pixel driving circuits PC and light-emitting elements disposed in the first island portion 11 may be one, two, or four or more.

Referring to FIG. 9, the substrate 100 corresponding to the first island portion 11 may include a first base layer 101, a first barrier layer 102, a second base layer 103, and a second barrier layer 104. The first base layer 101 and the second base layer 103 may each include polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. The first barrier layer 102 and the second barrier layer 104 may each include an inorganic insulating material, such as silicon oxide, silicon nitride, or silicon oxynitride.

A buffer layer 111 may be disposed on the substrate 100, and the pixel driving circuit PC may be disposed on the buffer layer 111. The buffer layer 111 may include an inorganic insulating material, such as silicon oxide, silicon nitride, or silicon oxynitride.

A thin-film transistor TFT may include a semiconductor layer Act, a gate electrode GE, a source electrode SE, and a drain electrode DE. FIG. 9 illustrates a top gate type thin-film transistor TFT in which the gate electrode GE is disposed on the semiconductor layer Act with a gate insulating layer 113 therebetween. However, according to another embodiment, the thin-film transistor TFT may be a bottom gate type.

The semiconductor layer Act may include polysilicon. In another embodiment, the semiconductor layer Act may include amorphous silicon, an oxide semiconductor, or an organic semiconductor. The gate electrode GE may include a low-resistance metal material. The gate electrode GE may include a conductive material including molybdenum (Mo), aluminum (Al), copper (Cu), titanium (Ti), and the like, and may include a single layer or mulitple layers including the conductive material described above.

The gate insulating layer 113 between the semiconductor layer Act and the gate electrode GE may include an inorganic insulating material, such as silicon oxide, nitrogen oxide, silicon oxynitride, aluminum oxide, or titanium oxide. The gate insulating layer 113 may include a single layer or mulitple layers including the inorganic insulating material described above.

The source electrode SE and the drain electrode DE may be disposed on the same layer, for example, a second interlayer insulating layer 117, and may include the same material. Each of the source electrode SE and the drain electrode DE may include a conductive material and may include a single layer or mulitple layers. The second interlayer insulating layer 117 may include an inorganic insulating material, such as silicon oxide, nitrogen oxide, silicon oxynitride, aluminum oxide, or titanium oxide, and may be a single layer or mulitple layers including the inorganic insulating material described above.

The storage capacitor Cst may include a first electrode CE1 and a second electrode CE2 that overlap each other with the first interlayer insulating layer 115 therebetween. The storage capacitor Cst may overlap the thin-film transistor TFT. In this regard, FIG. 9 illustrates an embodiment in which the gate electrode GE of the thin-film transistor TFT is the first electrode CE1 of the storage capacitor Cst. In another embodiment, the storage capacitor Cst may not overlap (e.g,. may be offset from) the thin-film transistor TFT. The storage capacitor Cst may be covered by the second interlayer insulating layer 117. The second electrode CE2 of the storage capacitor Cst may include a conductive material and may include a single layer or mulitple layers. The first interlayer insulating layer 115 may be disposed between the gate insulating layer 113 and the second interlayer insulating layer 117. The first interlayer insulating layer 115 may include an inorganic insulating material, such as silicon oxide, nitrogen oxide, silicon oxynitride, aluminum oxide, or titanium oxide, and may be a single layer or mulitple layers including the inorganic insulating material described above.

An inorganic insulating layer IOL on the substrate 100 may include, for example, the buffer layer 111, the gate insulating layer 113, the first interlayer insulating layer 115, and the second interlayer insulating layer 117.

A first organic insulating layer 119 may be disposed on the second interlayer insulating layer 117. A second organic insulating layer 121 may be disposed on the first organic insulating layer 119. The first organic insulating layer 119 and the second organic insulating layer 121 may each include an organic insulating material, such as polyimide.

A second voltage line VSSL may be disposed on the second organic insulating layer 121. A third organic insulating layer 123 may be disposed on the second organic insulating layer 121 and the second voltage line VSSL. The third organic insulating layer 123 may include an organic insulating material, such as polyimide. The second voltage line VSSL may include a conductive material and may include a single layer or mulitple layers.

A first electrode pad 241 and a second electrode pad 242 may be disposed on the third organic insulating layer 123. The first electrode pad 241 may be electrically connected to the thin-film transistor TFT through a first connection electrode CM1 between the first organic insulating layer 119 and the second organic insulating layer 121 and a second connection electrode CM2 between the second organic insulating layer 121 and the third organic insulating layer 123. An inorganic light-emitting diode 230 on the first electrode pad 241 and the second electrode pad 242 is the same as described above with reference to FIG. 7B. A light-emitting diode, for example, the inorganic light-emitting diode 230, may be protected by an encapsulation layer 300. The encapsulation layer 300 may include an inorganic encapsulation layer and/or an organic encapsulation layer or may include an organic material, such as a resin. FIG. 9 illustrates an embodiment in which the light-emitting diode is the inorganic light-emitting diode 230 described above with reference to FIG. 7B, but in another embodiment, the light-emitting diode may be an organic light-emitting diode 220 described above with reference to FIG. 7A.

Referring to FIG. 8B, the first bridge portion 12 may include a plurality of wirings WL electrically connected to the pixel driving circuits PC respectively disposed in the adjacent first island portions 11. As described above, the wirings WL may include a signal line (e.g., a gate line, a data line, etc.) configured to provide an electrical signal to the transistor included in the pixel driving circuit PC of the first island portion 11 or may include a voltage line (e.g., a driving voltage line, an initialization voltage line, etc.) configured to provide a voltage to the transistor included in the pixel driving circuit PC of the first island portion 11. Although FIG. 8B illustrates an embodiment in which the plurality of wirings WL, for example, first to third wirings WL1, WL2, and WL3, are disposed on the first bridge portion 12, the present disclosure is not limited thereto. In another embodiment, one wiring WL may be disposed on the first bridge portion 12.

Referring to FIG. 9, in an embodiment, the substrate 100 corresponding to the first bridge portion 12 may have the same stack structure as the substrate 100 corresponding to the first island portion 11. In an embodiment, the substrate 100 corresponding to the first bridge portion 12 may include a first base layer 101, a first barrier layer 102, a second base layer 103, and a second barrier layer 104. In another embodiment, the substrate 100 corresponding to the first bridge portion 12 may have a different stack structure from the substrate 100 corresponding to the first island portion 11. The substrate 100 corresponding to the first bridge portion 12 may have a structure of the first base layer 101 and the second base layer 103.

The inorganic insulating layer IOL may not be disposed on the substrate 100 corresponding to the first bridge portion 12 but an insulating layer OL, the first organic insulating layer 119, and the second organic insulating layer 121 may be disposed on the substrate 100 corresponding to the first bridge portion 12. The insulating layer OL may include an organic insulating material, such as polyimide. In an embodiment, the insulating layer OL may have a thickness corresponding to the inorganic insulating layer IOL. In some embodiments, the insulating layer OL may be omitted.

The plurality of wirings WL, for example, the first to third wirings WL1, WL2, and WL3, may be disposed on different layers and electrically connected to the same pixel driving circuit PC. For example, the first wiring WL1 may be disposed between the second organic insulating layer 121 and the third organic insulating layer 123, the second wiring WL2 may be disposed between the first organic insulating layer 119 and the second organic insulating layer 121, and the third wiring WL3 may be disposed between the insulating layer OL and the first organic insulating layer 119. However, the present disclosure is not limited thereto, and in another embodiment, at least some of the first to third wirings WL1, WL2, and WL3 may be disposed on the same layer.

FIGS. 10A and 10B are enlarged plan views of the island portion 10 and the bridge portion 20 of the display device (see, e.g., 1 in FIG. 1) according to an embodiment.

FIG. 10A is a plan view of the island portion 10 and the bridge portion 20 before the display device (see, e.g., 1 in FIG. 1) is stretched, and FIG. 10B is a plan view of the island portion 10 and the bridge portion 20 after the display device (see, e.g., 1 in FIG. 1) is stretched.

FIGS. 10A and 10B illustrate only two island portions 10 and one bridge portion 20 for convenience of explanation, but the display device (see, e.g., 1 in FIG. 1) may include a plurality of island portions 10 and a plurality of bridge portions 20.

For convenience of explanation, FIGS. 10A and 10B illustrate that one bridge portion 20 is connected to one island portion 10, but a plurality of bridge portions 20 may be connected to one island portion 10.

Referring to FIGS. 10A and 10B, the plurality of island portions 10 may include the plurality of first island portions 11 and the plurality of second island portions 21 described above with reference to FIGS. 4A to 4C. The plurality of island portions 10 may include a driving circuit. For example, the plurality of island portions 10 may include at least one of the gate driving circuit (see, e.g., GDC in FIG. 3), the data driving circuit (see, e.g., DDC in FIG. 3), and the pixel driving circuit (see, e.g., PC in FIG. 5). The plurality of bridge portions 20 may include the plurality of first bridge portions 12 and the plurality of second bridge portions 22 described above with reference to FIGS. 4A to 4C.

The plurality of island portions 10 may be spaced apart from each other. The plurality of bridge portions 20 may connect two adjacent island portions 10 to each other. The plurality of bridge portions 20 may be provided in a curved shape between two island portions 10 disposed adjacent to each other. Hereinafter, an area of the plurality of bridge portions 20 in contact with the island portion 10 is referred to as area A, a concave area of the central portion thereof is referred to as area B, and a convex area of the central portion thereof is referred to as area C.

Referring to FIG. 10B, a computer simulation result shows that after the display device (see, e.g., 1 in FIG. 1) is stretched, an approximate elongation rate in area A of the plurality of bridge portions is about 180%, an approximate elongation rate of area B is about 100%, and an approximate elongation rate of area C is about 50%. Thus, the elongation rate is the greatest in a portion of the plurality of bridge portions that is directly connected to the plurality of island portions 10. Because the elongation rate in a portion of the plurality of bridge portions in contact with the plurality of island portions 10 is higher (or is relatively high), the overall durability and elongation rate of the bridge portion 20 may be improved.

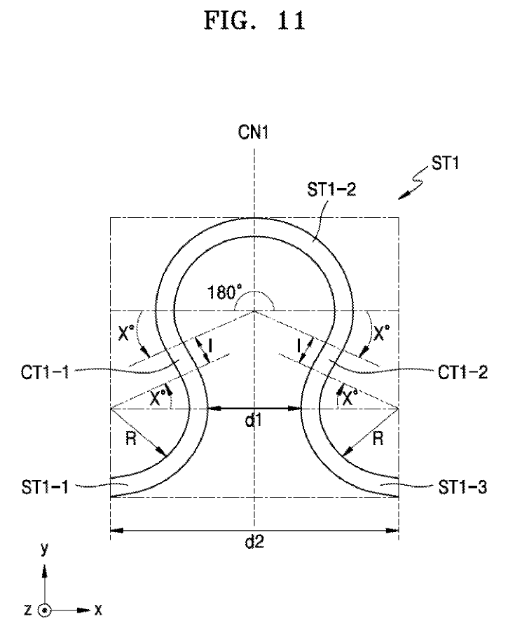

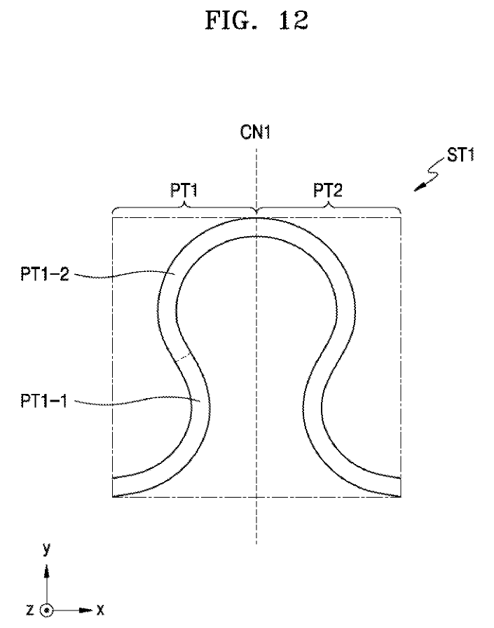

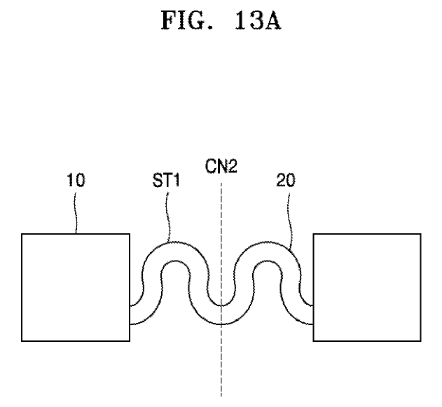

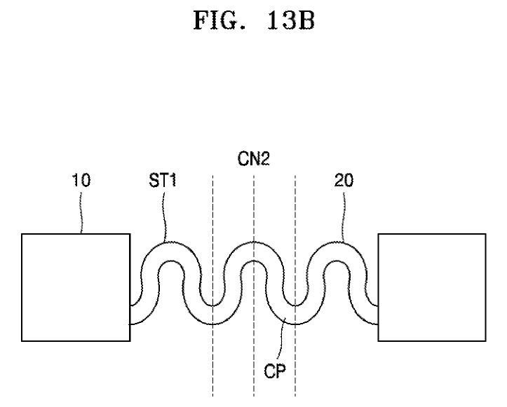

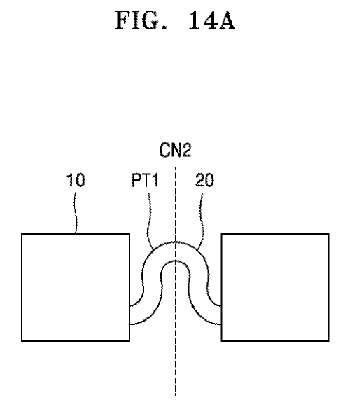

FIGS. 11 and 12 are schematic plan views of a first structure ST1 according to an embodiment.

Referring to FIGS. 11 and 12, at least one of the plurality of bridge portions (see,e.g., 20 in FIG. 10A) may include at least a portion of the first structure ST1.

Referring to FIG. 11, the first structure ST1 may have a curved shape and may include a first-1 structure ST1-1, a first-2 structure ST1-2, a first-3 structure ST1-3, a first-1 connection structure CT1-1, and a first-2 connection structure CT1-2.

The first-1 structure ST1-1 may have an arc shape with a central angle of (90+X) degrees. The first-2 structure ST1-2 may have an arc shape with a central angle of (180+2X) degrees. The first-3 structure ST1-3 may have an arc shape with a central angle of (90+X) degrees. The radii of the first-1 structure ST1-1, the first-2 structure ST1-2, and the first-3 structure ST1-3 may be equal to each other. The first-1 structure ST1-1 and the first-3 structure ST1-3 may be connected to the first-2 structure ST1-2.

The first structure ST1 may be disposed symmetrically with respect to a first center line CN1, which is an imaginary line crossing (or bisecting) the first-2 structure ST1-2. The first center line CN1 may pass through the center of the first-2 structure ST1-2. The first-1 structure ST1-1 may be disposed to be convex in a direction toward the first center line CN1. The first-3 structure ST1-3 may be disposed to be convex in a direction toward the first center line CN1. In such a structure, a distance d2 between the center of the first-1 structure ST1-1 and the center of the first-3 structure ST1-3 may be greater than a diameter 2R of the first-2 structure ST1-2. In addition, a shortest distance d1 between the first-1 structure ST1-1 and the first-3 structure ST1-3 may be less than the diameter 2R of the first-2 structure ST1-2.

The first-1 connection structure CT1-1 may have a straight line shape and may connect the first-1 structure ST1-1 to the first-2 structure ST1-2. The first-1 connection structure CT1-1 may be in contact with each of the first-1 structure ST1-1 and the first-2 structure ST1-2 to smoothly connect the first-1 structure ST1-1 to the first-2 structure ST1-2. The first-2 connection structure CT1-2 may be provided in a straight line and may connect the first-2 structure ST1-2 to the first-3 structure ST1-3. In such a structure, the first-1 structure ST1-1, the first-1 connection structure CT1-1, the first-2 structure ST1-2, the first-2 connection structure CT1-2, and the first-3 structure ST1-3 may be sequentially connected. The first-2 connection structure CT1-2 may be in contact with each of the first-2 structure ST1-2 and the first-3 structure ST1-3 to smoothly connect the first-2 structure ST1-2 to the first-3 structure ST1-3. A length l of the first-1 connection structure CT1-1 may be equal to a length I of the first-2 connection structure CT1-2.

Referring to FIG. 12, the first structure ST1 may be divided into a first portion PT1 and a second portion PT2. The first portion PT1 and the second portion PT2 may be disposed symmetrically with respect to the first center line CN1. As illustrated in FIG. 12, a portion of the first structure ST1 disposed to the left of the first center line CN1 may be referred to as a first portion PT1, and a portion of the first structure ST1 disposed to the right of the first center line CN1 may be referred to as a second portion PT2. The first portion PT1 may be divided into a first-1 portion PT1-1 and a first-2 portion PT1-2. The first-1 portion PT1-1 and a first-2 portion PT1-2 may have the same shape. The first-1 portion PT1-1 and the first-2 portion PT1-2 may be divided with respect to the center of the first-1 connection structure (see, e.g., CT1-1 in FIG. 11) of the first portion PT1 as a boundary.

FIGS. 13A to 15B are enlarged plan views of the island portion 10 and the bridge portion 20 of the display device (see, e.g., 1 in FIG. 1) according to various embodiments.

FIGS. 13A to 15B illustrate only two island portions 10 and one bridge portion 20 for convenience of explanation, but the display device (see, e.g., 1 in FIG. 1) may include a plurality of island portions 10 and a plurality of bridge portions 20.

For convenience of explanation, FIGS. 13A to 15B illustrate that one bridge portion 20 is connected to one island portion 10, but a plurality of bridge portions 20 may be connected to one island portion 10.

Referring to FIGS. 12 to 15B, at least one of the plurality of bridge portions 20 may include at least a portion of the first structure ST1 connected to at least one of the plurality of island portions 10. For example, at least a portion of the first structure ST1 may be directly connected to at least one of the plurality of island portions 10.

Referring to FIGS. 12 to 13B, at least one of the plurality of bridge portions 20 may include a first portion PT1 and a second portion PT2. For example, at least one of the plurality of bridge portions 20 may include the entire first structure ST1.

For example, as illustrated in FIG. 13A, at least one of the plurality of bridge portions 20 may include two first structures ST1. The two first structures ST1 may be connected to each other with respect to a second center line CN2 as a boundary. Each of the two first structures ST1 may be connected to at least one of the plurality of island portions 10.

For example, as illustrated in FIG. 13B, at least one of the plurality of bridge portions 20 may include two first structures ST1 and a connection portion CP. Each of the two first structures ST1 may be connected to at least one of the plurality of island portions 10. The two first structures ST1 may be spaced apart from each other. The connection portion CP may be disposed between the two first structures ST1 to connect the two first structures ST1 to each other. For example, the connection portion CP may have the same shape as the first structure ST1.

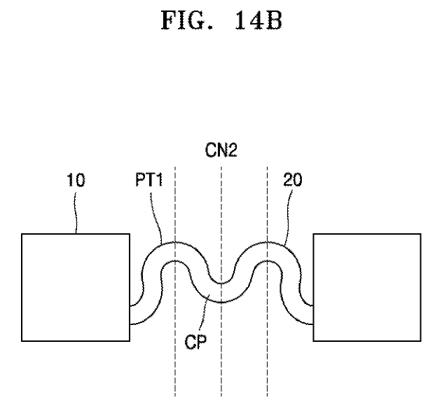

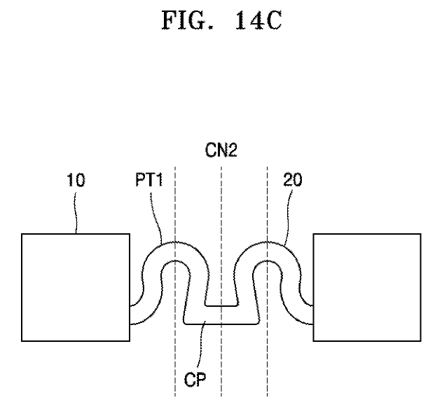

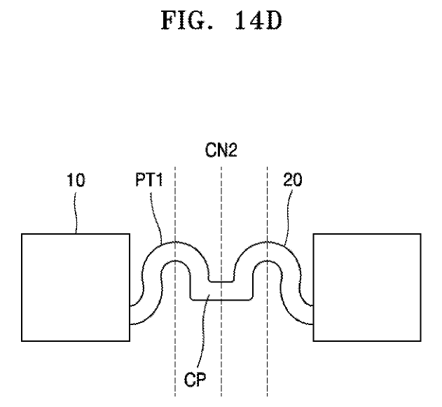

Referring to FIGS. 12 and 14A to 14D, at least one of the plurality of bridge portions 20 may include a first portion PT1. For example, at least one of the plurality of bridge portions 20 may include a portion of the first structure ST1.

For example, as illustrated in FIG. 14A, at least one of the plurality of bridge portions 20 may include two first portions PT1. The two first portions PT1 may be connected to each other with respect to a second center line CN2 as a boundary. Each of the two first portions PT1 may be connected to at least one of the plurality of island portions 10.

For example, as illustrated in FIGS. 14B to 14D, at least one of the plurality of bridge portions 20 may include two first portions PT1 and a connection portion CP. Each of the two first portions PT1 may be connected to at least one of the plurality of island portions 10. The two first portions PT1 may be spaced apart from each other. The connection portion CP may be disposed between the two first portions PT1 to connect the two first portions PT1 to each other. For example, the connection portion CP may have only a curved shape, as illustrated in FIG. 14B. For example, the connection portion CP may have a combination of a curved shape and a straight shape, as illustrated in FIGS. 14C and 14D.

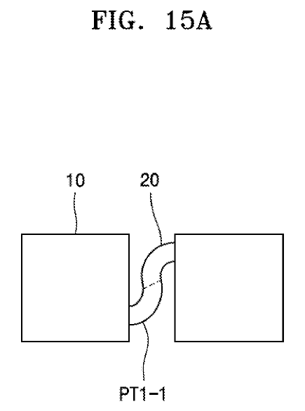

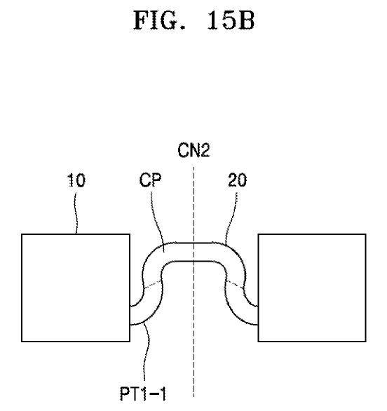

Referring to FIGS. 12, 15A, and 15B, at least one of the plurality of bridge portions 20 may include a first-1 portion PT1-1. For example, at least one of the plurality of bridge portions 20 may include a portion of the first structure ST1.

For example, as illustrated in FIG. 15A, at least one of the plurality of bridge portions 20 may include two first-1 portions PT1-1. The two first-1 portions PT1-1 may be connected to each other in an ‘S’ shape. Each of the two first-1 portions PT1-1 may be connected to at least one of the plurality of island portions 10.

For example, as illustrated in FIG. 15B, at least one of the plurality of bridge portions 20 may include two first-1 portions PT1-1 and a connection portion CP. Each of the two first-1 portions PT1-1 may be connected to at least one of the plurality of island portions 10. The two first-1 portions PT1-1 may be spaced apart from each other. The connection portion CP may be disposed between the two first-1 portions PT1-1 to connect the two first-1 portions PT1-1 to each other. For example, the connection portion CP may include at least one of a curved shape or a straight shape, as illustrated in FIG. 15B.

The embodiments described above with reference to FIGS. 13A to 15B are only examples, and the shape of the plurality of bridge portions 20 is not limited thereto. The shape of the plurality of bridge portions 20 may be variously modified according to various design considerations as long as the shape of the plurality of bridge portions 20 includes at least a portion of the first structure ST1.

FIG. 16 is a graph showing strain of the bridge portion (see, e.g., 20 in FIG. 10A) with respect to X.

In FIG. 16, the horizontal axis represents X described above with reference to FIG. 11, and the vertical axis represents the elongation rate of a portion (e.g., region A) of the bridge portion 20 adjacent to the island portion 10 described above with reference to FIG. 10A and FIG. 10B.

The results shown in FIG. 16 were derived through computer simulation.

Referring to FIGS. 10A to 11 and 16, the absolute value of the slope of the graph is the greatest in the section where X is in a range of 0 to 5. For example, in the section where X is in a range of 0 to 5, strain decreases rapidly as X increases.

In the section where X is 5 or more, the absolute value of the slope of the graph may be relatively small compared to the section where X is in a range of 0 to 5. That is, in the section where X is 5 or more, the change in strain with respect to X is not great compared to the section where X is in a range of 0 to 5. In particular, in the section where X is in a range of 15 to 30, strain increases as X increases.

In an embodiment, X may be 5 or more. In the section where X is in a range of 0 to 5, strain decreases rapidly as X increases. Accordingly, X to be relatively large to reduce or decrease strain. However, in the section where X is 5 or more, the change in strain with respect to X is not great. Accordingly, X may be variously set according to other design considerations. For example, X may be 15. When X is 15, strain with respect to X may be the smallest.

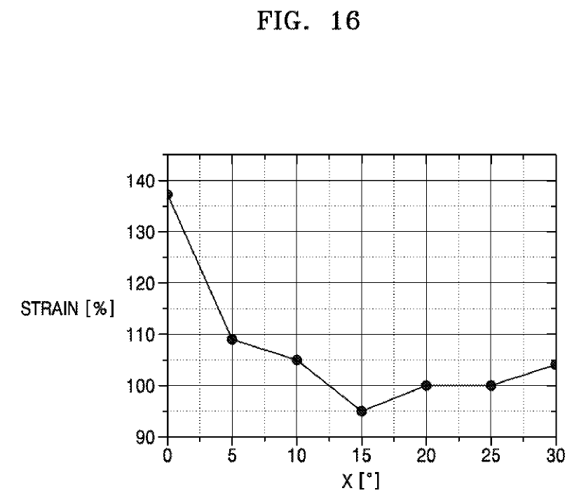

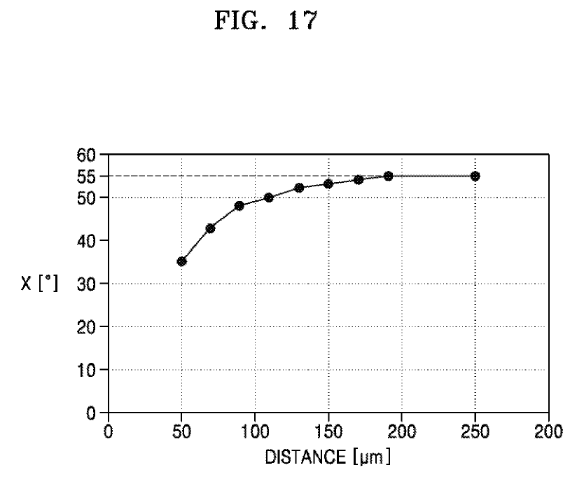

FIG. 17 is a graph showing X with respect to a distance between two adjacent island portions (see, e.g., 10 in FIG. 10A).

In FIG. 17, the vertical axis represents X described above with reference to FIG. 11, and the horizontal axis represents the minimum distance between two adjacent island portions (see, e.g., 10 in FIG. 10A) for X before the display device (see, e.g., 1 in FIG. 1) is stretched. When the distance between two adjacent island portions (see, e.g., 10 in FIG. 10A) is greater than a specified value, the resolution of the display device (see, e.g., 1 in FIG. 1) may deteriorate.

Referring to FIGS. 10A to 11 and 17, as the distance between two adjacent island portions 10 increases, the absolute value of the slope of the graph decreases. In addition, when the distance between two adjacent island portions 10 gradually increases to 250 μm, X is saturated at 55. That is, when X is greater than 55, the minimum distance between two adjacent island portions 10 for X increases rapidly. Thus, in an embodiment, X may be about 55 or less. In an embodiment, the distance between two adjacent island portions 10 may be about 250 μm or less.

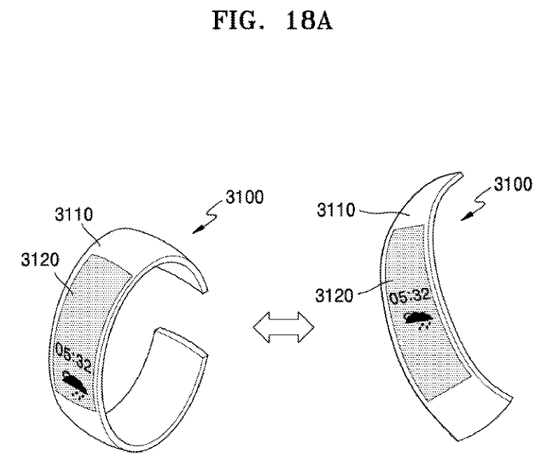

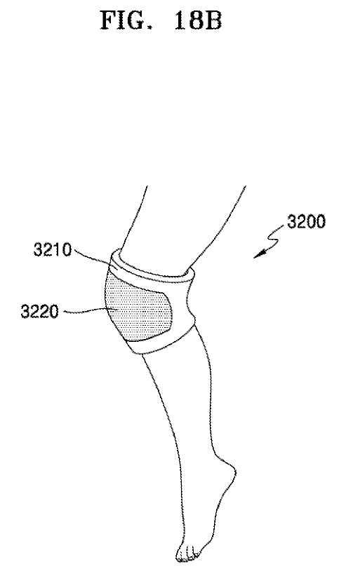

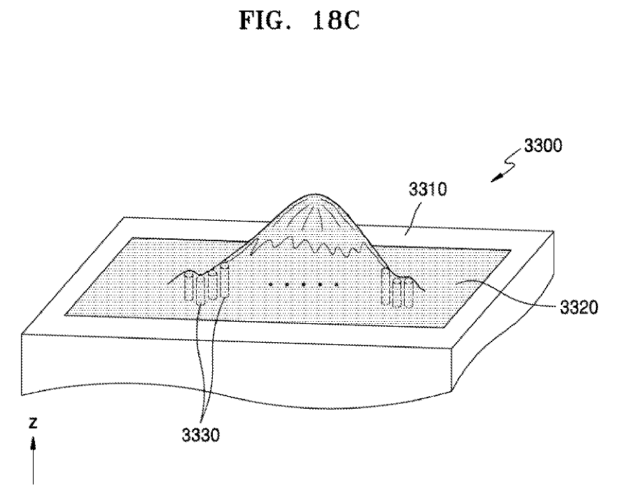

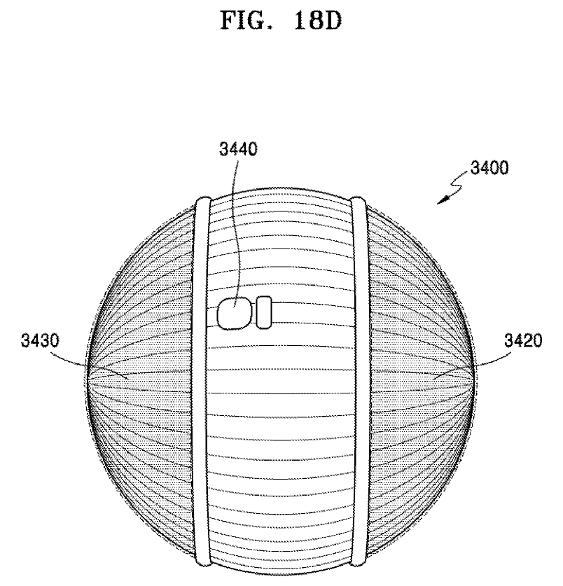

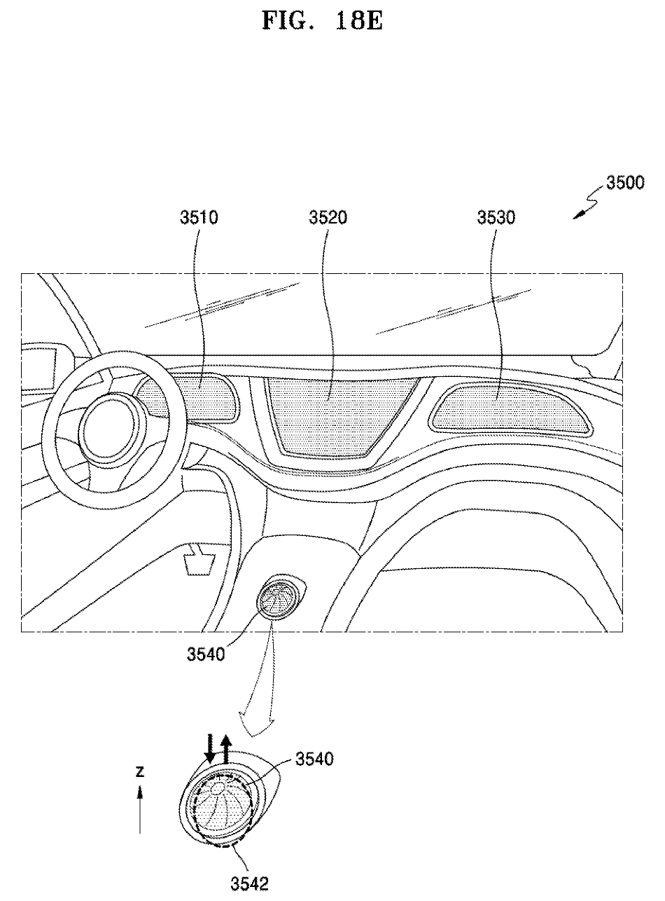

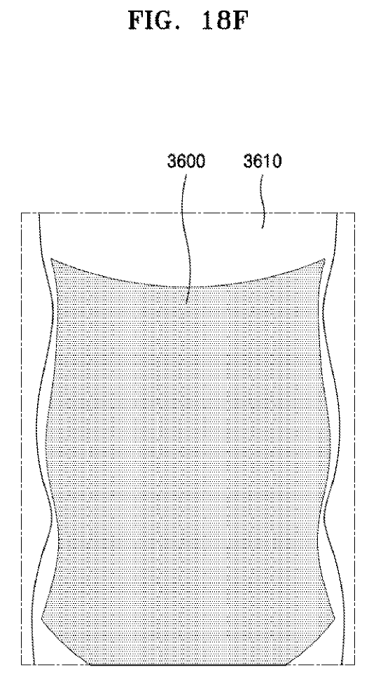

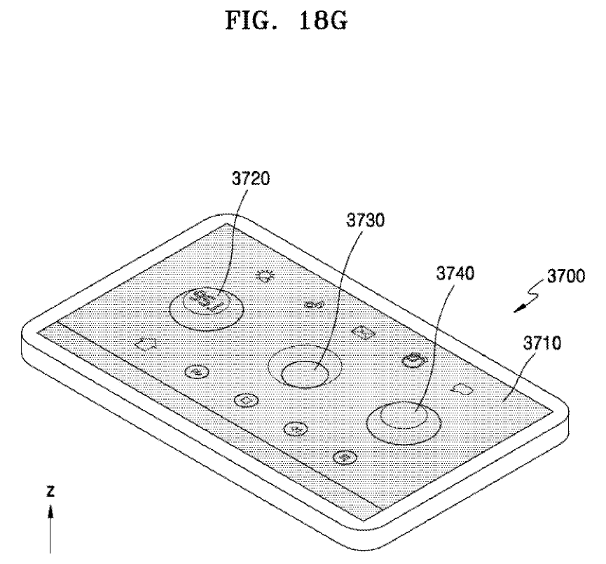

FIGS. 18A to 18G are perspective views schematically illustrating an electronic apparatus including the display device (see, e.g., 1 in FIG. 1) according to various embodiments.

The stretchable display device (see, e.g., 1 in FIG. 1) according to the embodiments described above may be used in various electronic apparatuses that provide images. The electronic apparatus refers to a device that uses electricity and provides (e.g., displays) an image.

Referring to FIG. 18A, the stretchable display device according to an embodiment may be used in a wearable electronic apparatus 3100 that is wearable on a part of a user's body. The wearable electronic apparatus 3100 may include a body 3110 and a display 3120 provided on the body 3110. The stretchable display device, according to embodiments, may be used as the display 3120 of the wearable electronic apparatus 3100. As illustrated in FIG. 18A, the wearable electronic apparatus 3100 may be variously modified. In an embodiment, the wearable electronic apparatus 3100 may be used as a smart watch or a smartphone according to a user’s choice.

FIG. 18B illustrates a medical electronic apparatus 3200. In an embodiment, the medical electronic apparatus 3200 may include a body 3210 and a light emitter 3220. The stretchable display device according to embodiments may be used as the light emitter 3220 of the medical electronic apparatus 3200. The light emitter 3220 may emit light in a certain wavelength band (e.g., infrared light, visible light, etc.) to a patient's body. In an embodiment, the body 3210 may include a stretchable fiber material and may have a structure that is wearable on the body of the user.

FIG. 18C illustrates an educational electronic apparatus 3300. In an embodiment, the educational electronic apparatus 3300 may include a display 3320 provided in a frame 3310. The display 3320 may use the stretchable display device according to embodiments. The display 3320 may provide images, such as a sea with waves, a mountain covered with snow, or a volcano with flowing lava. In this case, the display 3320 may extend in the height direction (e.g., the +z direction) to reflect the height of the waves, the mountain, or the volcano. In some embodiments, a portion of the display 3320 may show the movement of lava in three dimensions by sequentially changing the height in the direction in which the lava flows. The educational electronic apparatus 3300 may include a plurality of pins (or stroke portions) 3330 disposed on the back surface of the display 3320 so that the display 3320 extends in the height direction. As the pins 3330 move in the third direction (e.g., the +z direction or the -z direction), the image displayed on the display 3320 may be implemented to have a three-dimensional height. Although FIG. 18C illustrates an embodiment of the educational electronic apparatus 3300, the use of the educational electronic apparatus 3300 is not limited as long as the educational electronic apparatus 3300 provides image information.

The electronic apparatuses illustrated in FIGS. 18A to 18C are described as being variable in shape, but the present disclosure is not limited thereto. As in the embodiments to be described below, the stretchable display device according to embodiments may be used in an electronic apparatus in which a part (e.g., a screen) capable of displaying an image is fixed.

FIG. 18D illustrates a robot 3400 as an electronic apparatus according to an embodiment. The robot 3400 may recognize movement or objects by using a camera 3440 and may display certain images to a user on displays 3420 and 3430. In some embodiments, because the stretchable display devices according to an embodiment may be stretched in various directions, as described above, the stretchable display devices may be assembled into a body frame having a hemispherical shape. Accordingly, the robot 3400 may include the hemispherical displays 3420 and 3430.

FIG. 18E illustrates a vehicle display device 3500 as an electronic apparatus according to an embodiment. The vehicle display device 3500 may include a cluster 3510, a center information display (CID) 3520, and/or a co-driver display (or a passenger display). Because the stretchable display device according to an embodiment may be stretched in various directions, the stretchable display device may be used in the cluster 3510, the CID 3520, and/or the co-driver display (or the passenger display), regardless of the shape of the internal frame of the vehicle.

Although FIG. 18E illustrates an embodiment in which the cluster 3510, the CID 3520, and/or the co-driver display (or the passenger display) are separated from each other, the present disclosure is not limited thereto. In another embodiment, two or more selected from the cluster 3510, the CID 3520, and the co-driver display (or the passenger display) may be integrally connected to each other.

In some embodiments, the vehicle display device 3500 may include a button 3540 configured to display an image. Referring to the enlarged view of FIG. 18E, the hemispherical button 3540 may include an object 3542 configured to provide the feeling of using the button while moving in the +z direction or the -z direction, and a stretchable display device disposed on the object 3542. In some embodiments, when the object 3542 has a three-dimensionally round surface, the stretchable display device may also have a three-dimensionally round surface.

FIG. 18F illustrates an electronic apparatus according to an embodiment being used an advertising or exhibition electronic apparatus 3600. In some embodiments, the advertising or exhibition electronic apparatus 3600 may be installed on a fixed structure 3610, such as a wall or a pillar. When the structure 3610 includes an uneven surface as illustrated in FIG. 18F, the advertising or exhibition electronic apparatus 3600 may also be arranged along the uneven surface of the structure 3610. In some embodiments, the advertising or exhibition electronic apparatus 3600 may be installed on the structure 3610 by using a heat-shrinkable film or the like.

FIG. 18G illustrates an electronic apparatus according to an embodiment being used as a controller 3700. The controller 3700 may include an image-type button. For example, the controller 3700 may include first to third button areas 3720, 3730, and 3740 in which a portion of a display 3710 protrudes in the +z direction or protrudes in the -z direction (or is recessed in the +z direction). In some embodiments, the first and third button areas 3720 and 3740 may protrude in the +z direction, and the second button area 3730 may protrude in the -z direction (or may be recessed in the +z direction).

According to one or more embodiments, damage to the display device due to stress concentration may be prevented and the overall elongation rate of the display device may be improved. However, the scope of the present disclosure is not limited thereto.

It should be understood that the embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display device comprising:
a plurality of island portions spaced apart from each other and comprising a driving circuit; and
a plurality of bridge portions connecting two adjacent ones of the island portions from among the plurality of island portions to each other,
wherein at least one of the plurality of bridge portions comprises a portion of a first structure that is connected to at least one of the plurality of island portions and has a curved shape,
wherein the first structure comprises a first-1 structure having an arc shape with a central angle of (90+X) degrees, and
wherein X is in a range of 5 to 55.

2. The display device of claim 1, wherein the first structure further comprises:
a first-2 structure having an arc shape with a central angle of (180+2X) degrees; and
a first-3 structure having an arc shape with a central angle of (90+X) degrees, and
wherein each of the first-1 structure and the first-3 structure is connected to the first-2 structure.

3. The display device of claim 2, wherein the first structure is divided into a first portion and a second portion arranged symmetrically with respect to a first center line crossing the first-2 structure.

4. The display device of claim 3, wherein at least one of the plurality of bridge portions comprises the first portion.

5. The display device of claim 3, wherein at least one of the plurality of bridge portions comprises the first portion and the second portion.

6. The display device of claim 2, wherein the first structure has a straight line shape and further comprises a first-1 connection structure connecting the first-1 structure to the first-2 structure.

7. The display device of claim 2, wherein the first structure has a straight line shape and further comprises a first-2 connection structure connecting the first-2 structure to the first-3 structure.

8. The display device of claim 2, wherein radii of the first-1 structure, the first-2 structure, and the first-3 structure are equal to each other.

9. The display device of claim 2, wherein a distance between a center of the first-1 structure and a center of the first-3 structure is greater than a diameter of the first-2 structure.

10. The display device of claim 2, wherein a shortest distance between the first-1 structure and the first-3 structure is less than a diameter of the first-2 structure.

11. The display device of claim 1, wherein X is 15.

12. The display device of claim 1, wherein a distance between two adjacent ones of the island portions from among the plurality of island portions is 250 μm or less.

13. An electronic apparatus comprising:
a plurality of island portions spaced apart from each other and comprising a driving circuit; and
a plurality of bridge portions connecting two adjacent ones of the island portions from among the plurality of island portions to each other,
wherein at least one of the plurality of bridge portions comprises a portion of a first structure that is connected to at least one of the plurality of island portions and has a curved shape,
wherein the first structure comprises a first-2 structure having an arc shape with a central angle of (180+2X) degrees, and
wherein X is in a range of 5 to 55.

14. The electronic apparatus of claim 13, wherein the first structure further comprises:
a first-1 structure having an arc shape with a central angle of (90+X) degrees; and
a first-3 structure having an arc shape with a central angle of (90+X) degrees, and
wherein each of the first-1 structure and the first-3 structure is connected to the first-2 structure.

15. The electronic apparatus of claim 14, wherein the first structure is divided into a first portion and a second portion arranged symmetrically with respect to a first center line crossing the first-2 structure.

16. The electronic apparatus of claim 15, wherein at least one of the plurality of bridge portions comprises the first portion.

17. The electronic apparatus of claim 15, wherein at least one of the plurality of bridge portions comprises the first portion and the second portion.

18. The electronic apparatus of claim 14, wherein the first structure has a straight line shape and further comprises a first-1 connection structure connecting the first-1 structure to the first-2 structure.

19. The electronic apparatus of claim 14, wherein the first structure has a straight line shape and further comprises a first-2 connection structure connecting the first-2 structure to the first-3 structure.

20. An electronic apparatus comprising:
a display device comprising:
a plurality of island portions spaced apart from each other and respectively comprising a driving circuit and a light emitting element connected to the driving circuit; and
a plurality of bridge portions connecting two adjacent ones of the island portions from among the plurality of island portions to each other, the plurality of bridge portions respectfully comprising wiring lines electrically connected to ones of the driving circuits,
wherein at least one of the plurality of bridge portions comprises a portion of a first structure that is connected to at least one of the plurality of island portions and has a curved shape,
wherein the first structure comprises a first-2 structure having an arc shape with a central angle of (180+2X) degrees, and
wherein X is in a range of 5 to 55.
